(19) United States
(12) Patent Application Publication
(10) Pub. No.: US 2025/0081329 A1
(43) Pub. Date: Mar. 6, 2025

(54) WIRING BOARD AND LAMINATED WIRING BOARD

(71) Applicant: SHINKO ELECTRIC INDUSTRIES CO., LTD., Nagano-shi (JP)

(72) Inventor: Yoshihiro Kobayashi, Nagano (JP)

(21) Appl. No.: 18/819,430

(22) Filed: Aug. 29, 2024

(30) Foreign Application Priority Data
Sep. 1, 2023 (JP) 2023-142447

(51) Int. Cl. H05K 1/02; H05K 3/00; H05K 3/42; H05K 3/46

(52) U.S. Cl. CPC H05K 1/0231; H05K 3/0026; H05K 3/429; H05K 3/467; H05K 3/4697; H05K 2201/10015; H05K 2203/0228

(57) ABSTRACT

A wiring board includes a first wiring structure and a second wiring structure. The first wiring structure includes: a mounting surface for a semiconductor element; and a back surface on an opposite side of the mounting surface. The second wiring structure is formed on the back surface of the first wiring structure. The first wiring structure further includes thin film layers, a cavity, an electronic component, and a filling resin layer. The thin film layers include laminated wiring layers and laminated insulating layers. The cavity is formed by cutting out at least one of the insulating layers of the thin film layers in a direction toward the mounting surface. The electronic component is located in the cavity. The filling resin layer fills the cavity, and further covers the electronic component.

### CROSS-REFERENCE TO RELATED APPLICATION

This application is based upon and claims the benefit of priority of the prior Japanese Patent Application No. 2023-142447, filed on Sep. 1, 2023, the entire contents of which are incorporated herein by reference.

### FIELD

The embodiment discussed herein is related to a wiring board, a laminated wiring board, and a manufacturing method of a wiring board.

### BACKGROUND

Conventionally, for example, there has been known a laminated wiring board obtained by laminating a relay board including minute wirings on a main board. In the above-mentioned laminated wiring board, for example, a semiconductor element is mounted on the relay board, and further an electronic component such as a capacitor is mounted on the main board at the periphery of the relay board in some cases. The electronic component mounted on the main board has function for reducing noise from the semiconductor element mounted on the relay board.

Japanese Laid-open Patent Publication No. 2001-144207

However, in the above-mentioned laminated wiring board, there arises a problem that noise from the semiconductor element may diffuse. Specifically, the semiconductor element mounted on the relay board and the electronic component mounted on the main board are connected to each other via wiring of the relay board and wiring of the main board, so that a length of the wiring between the semiconductor element and the electronic component becomes long, thereby leading increase in inductance of the above-mentioned wiring. As a result, there presents possibility that noise from the semiconductor element is not sufficiently reduced in the electronic component so as to diffuse into the periphery of the semiconductor element.

### SUMMARY

According to an aspect of an embodiment, a wiring board includes a first wiring structure that includes a mounting surface for a semiconductor element and a back surface on an opposite side of the mounting surface; and a second wiring structure that is formed on the back surface of the first wiring structure, wherein the first wiring structure includes: thin film layers that include laminated wiring layers and laminated insulating layers; a cavity that is formed by cutting out at least one of the insulating layers of the thin film layers in a direction toward the mounting surface; an electronic component that is located in the cavity; and a filling resin layer that fills the cavity, and further covers the electronic component.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a structure of a board according to an embodiment;

FIG. 2 is a diagram illustrating a configuration of a first wiring board according to the embodiment;

FIG. 3 is a flowchart illustrating a method for manufacturing the first wiring board according to the embodiment;

FIG. 4 is a diagram illustrating a specific example of a reinforcing insulating layer forming process;

FIG. 5 is a diagram illustrating a specific example of a via hole forming process;

FIG. 6 is a diagram illustrating a specific example of a seed layer forming process;

FIG. 7 is a diagram illustrating a specific example of a resist layer forming process;

FIG. 8 is a diagram illustrating of a specific example of an electrolytic copper plating process;

FIG. 9 is a diagram illustrating a specific example of a resist layer removing process;

FIG. 10 is a diagram illustrating a specific example of a solder applying process;

FIG. 11 is a diagram illustrating a specific example of an adhesion layer forming process;

FIG. 12 is a flowchart illustrating a method for manufacturing the board according to the embodiment;

FIG. 13 is a diagram illustrating a specific example of a first wiring board mounting process;

FIG. 14 is a diagram illustrating a specific example of a glass support member peeling process;

FIG. 15 is a diagram illustrating a configuration example of a semiconductor device;

FIG. 16 is a flowchart illustrating a method for forming a first wiring structure according to the embodiment;

FIG. 17 is a diagram illustrating a specific example of a glass support member;

FIG. 18 is a diagram illustrating a specific example of the seed layer forming process;

FIG. 19 is a diagram illustrating a specific example of the resist layer forming process;

FIG. 20 is a diagram illustrating a specific example of an electrode pad forming process;

FIG. 21 is a diagram illustrating a specific example of a resist layer removing process;

FIG. 22 is a diagram illustrating a specific example of a seed layer removing process;

FIG. 23 is a diagram illustrating a specific example of an insulating layer forming process;

FIG. 24 is a diagram illustrating a specific example of the seed layer forming process;

FIG. 25 is a diagram illustrating a specific example of the resist layer forming process;

FIG. 26 is a diagram illustrating a specific example of the electrolytic copper plating process;

FIG. 27 is a diagram illustrating a specific example of the resist layer removing process;

FIG. 28 is a diagram illustrating a specific example of the seed layer removing process;

FIG. 29 is a diagram illustrating a specific example of a cavity forming process;

FIG. 30 is a diagram illustrating a specific example of an electronic component arranging process;

FIG. 31 is a diagram illustrating a specific example of an electronic component embedding process;

FIG. 32 is a diagram illustrating a specific example of a via hole forming process;

FIG. 33 is a diagram illustrating a specific example of the seed layer forming process;

FIG. 34 is a diagram illustrating a specific example of the resist layer forming process;

FIG. 35 is a diagram illustrating a specific example of the electrolytic copper plating process;

FIG. 36 is a diagram illustrating a specific example of the resist layer removing process;

FIG. 37 is a diagram illustrating a specific example of the seed layer removing process;

FIG. 38 is a diagram illustrating a specific example of the insulating layer forming process;

FIG. 39 is a diagram illustrating a configuration of a first wiring board according to a modification 1 of the embodiment;

FIG. 40 is a diagram illustrating a specific example of the cavity forming process;

FIG. 41 is a diagram illustrating a specific example of the electronic component arranging process;

FIG. 42 is a diagram illustrating a configuration of a first wiring board according to a modification 2 of the embodiment;

FIG. 43 is a diagram illustrating of a configuration of a first wiring board according to a modification 3 of the embodiment;

FIG. 44 is a diagram illustrating a specific example of the cavity forming process;

FIG. 45 is a diagram illustrating a specific example of the electronic component arranging process;

FIG. 46 is a diagram illustrating a configuration of a first wiring board according to a modification 4 of the embodiment;

FIG. 47 is a diagram illustrating a specific example of a concave part forming process; and

FIG. 48 is a diagram illustrating a specific example of the electronic component arranging process.

### DESCRIPTION OF EMBODIMENT

Hereinafter, an embodiment of a wiring board, a laminated wiring board, and a method for manufacturing the wiring board disclosed in the present application will be described in detail with reference to the drawings. Note that the embodiment is not intended to limit the present invention.

### Embodiment

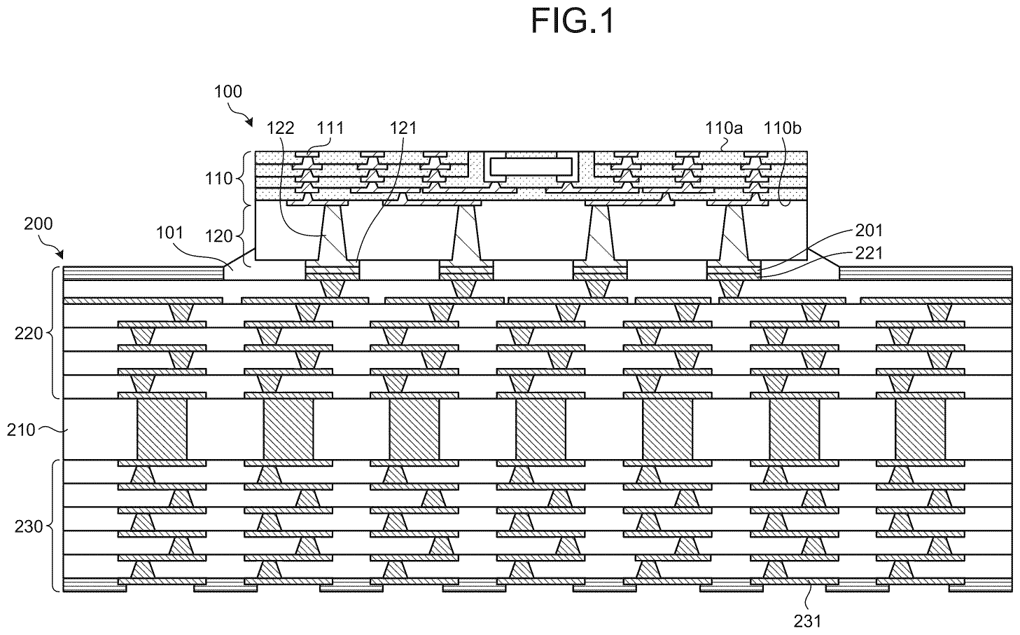

FIG. 1 is a diagram illustrating a structure of a board according to the embodiment. In FIG. 1, a cross section of the board according to the embodiment is schematically illustrated. The board illustrated in FIG. 1 is a laminated wiring board obtained by laminating a first wiring board 100 on a second wiring board 200. In the following description, a direction from the second wiring board 200 to the first wiring board 100 is defined to be upward, and a direction from the first wiring board 100 to the second wiring board 200 is defined to be downward. However, the first wiring board 100 and the second wiring board 200 may be inverted upside down when manufactured and used, for example, and further may be manufactured and used in an arbitrary posture.

The first wiring board 100 is a relay board including a first wiring structure 110 in which a plurality of thin film layers is laminated and a second wiring structure 120 that serves as a base layer. Electrode pads 111 are formed on an upper surface 110a of the first wiring structure 110. The electrode pads 111 are formed of a conductor such as copper, so as to be connection terminals in a case where a semiconductor element is bonded to the first wiring board 100. In other words, in a case where a semiconductor element is bonded to the first wiring board 100, the semiconductor element is mounted on the upper surface 110a of the first wiring structure 110, and the electrode pads 111 is bonded to an electrode of the semiconductor element by using solder. Furthermore, electrode pads 121 are formed on a lower surface of the second wiring structure 120. The electrode pads 121 are formed of a conductor such as copper, so as to be connection terminals in a case where the first wiring board 100 is bonded to the second wiring board 200. Furthermore, the electrode pads 121 are connected with wirings of the first wiring structure 110 via vias 122 in the second wiring structure 120.

The second wiring board 200 is a main board including a core layer 210, a buildup layer 220 laminated on an upper surface of the core layer 210, and a buildup layer 230 laminated on a lower surface of the core layer 210. Electrode pads 221 are formed on an upper surface of the buildup layer 220, and electrode pads 231 are formed on a lower surface of the buildup layer 230. The electrode pads 221 are formed of a conductor such as copper, so as to be connection terminals in a case where the second wiring board 200 is bonded to the first wiring board 100. The electrode pads 231 are formed of a conductor such as copper, so as to be connection terminals in a case where the second wiring board 200 is bonded to an external component such as a mother board. Furthermore, in the core layer 210, the buildup layer 220, and the buildup layer 230; wirings are formed, which electronically connect the electrode pads 221 and the electrode pads 231 to each other.

The first wiring board 100 is mounted on the second wiring board 200. In other words, the electrode pads 121 that are the connection terminals of the first wiring board 100, and the electrode pads 221 that are the connection terminals of the second wiring board 200 are bonded to each other by using solder 201. An adhesion layer 101 is formed between a lower surface (namely, lower surface of second wiring structure 120) of the first wiring board 100 and an upper surface of the second wiring board 200. The adhesion layer 101 bonds the first wiring board 100 to the second wiring board 200 while covering a part of a side surface of the first wiring board 100. For example, insulating resin such as epoxy resin and polyimide resin is used as the bonding layer 101.

As described above, the first wiring board 100 and the second wiring board 200 to be bonded to each other by the adhesion layer 101 and the solder 201 are separately manufactured. The first wiring board 100 is manufactured on a support member whose material is glass. In other words, on the glass support member, the first wiring structure 110 is formed in a state where the upper surface 110a of the first wiring structure 110 faces the glass support member, and the second wiring structure 120 is laminated on a lower surface 110b of the first wiring structure 110 whereby the first wiring board 100 is manufactured. Furthermore, the first wiring board 100 manufactured on the glass support member and the second wiring board 200 are bonded to each other by the adhesion layer 101 and the solder 201, and then the glass support member is peeled off from the first wiring board 100.

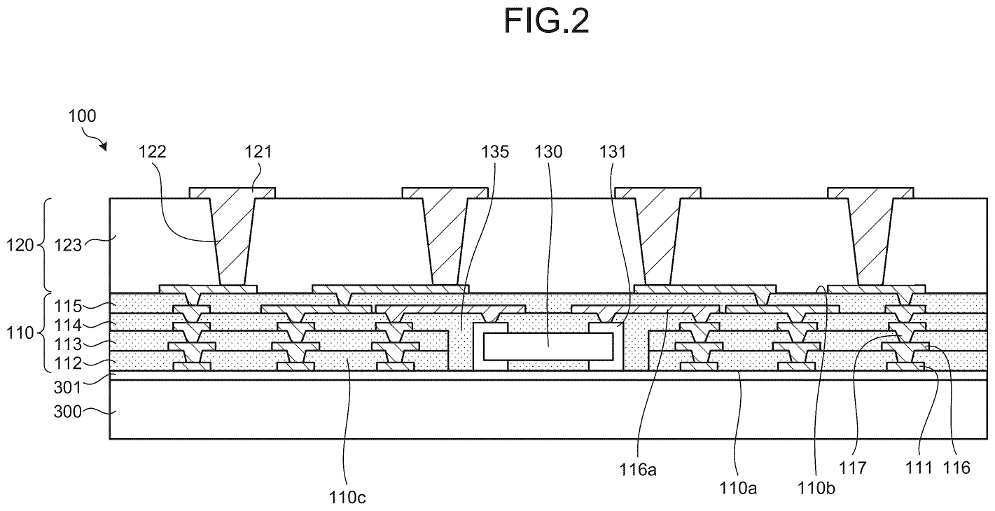

Herein, with reference to FIG. 2, a configuration of an intermediate structure that is formed in the process for manufacturing the first wiring board 100 will be explained. FIG. 2 is a diagram illustrating a configuration of the first wiring board 100 according to the embodiment. The intermediate structure of the first wiring board 100 illustrated in FIG. 2 includes a glass support member 300, the first wiring structure 110 formed over the glass support member 300, and the second wiring structure 120 laminated on the lower surface 110b of the first wiring structure 110. The first wiring structure 110 and the second wiring structure 120 are inverted upside down when being generated on the glass support member 300. Furthermore, an electronic component 130 is embedded in the first wiring structure 110.

The glass support member 300 is a support member whose upper surface is flat, and a peeling layer 301 is formed on the above-mentioned upper surface. A silicone-based or acrylic adhesive material is used as the peeling layer 301, for example. The glass support member 300 is peeled off from the peeling layer 301 so as to obtain the first wiring board 100. For example, the first wiring board 100 manufactured on the glass support member 300 and the second wiring board 200 are bonded to each other by using the adhesion layer 101 and the solder 201, and then the glass support member 300 is peeled off from the peeling layer 301. Note that a support member other than the glass support member 300 may be used, and metal, silicon, ceramics or the like may be used as material of the above-mentioned support member.

The first wiring structure 110 is a structure including a first thin film layer 112, a second thin film layer 113, a filling resin layer 114, and a third thin film layer 115; and having a thickness of approximately 30 μm to 50 μm. Herein, a case is exemplified in which four thin film layers including the filling resin layer 114 are laminated on an upper surface of the glass support member 300 so as to form the first wiring structure 110; however, the number of the thin film layers laminated on the upper surface of the glass support member 300 is not limited to four. Each of the first to the third thin film layers 112, 113, and 115 and the filling resin layer 114 is a thin film layer obtained by forming a corresponding wiring layer 116 including a minute wiring on an insulating layer 110c. The wiring layers 116 of the first to third thin film layers 112, 113, and 115, and that of the filling resin layer 114 are connected by vias 117 each of which penetrates the corresponding insulating layer 110c. The vias 117 are formed in a truncated cone shape whose diameter on a side of the electrode pads 111 is smaller than that on a side of the electrode pads 121.

The insulating layers 110c of the first to third thin film layers 112, 113, and 115, and the filling resin layer 114 are formed by using a photosensitive insulation resin material, for example. For example, photosensitive insulating resin such as epoxy resin and polyimide resin may be used as the insulating layer 110c. In a case where the minute wiring layers 116 are formed over the insulating layers 110c, resist is formed on an upper surface of the insulating layers 110c, and pattering and electrolytic copper plating are performed thereon.

The electrode pads 111 are embedded in the first thin film layer 112 that is the lowest layer. The electrode pads 111 are formed of a conductor such as copper, so as to be connection terminals in a case where a semiconductor element is bonded to the first wiring board 100. A surface (lower surface) of the first thin film layer 112, which is located at an upper surface side of the glass support member 300, forms the upper surface 110a of the first wiring structure 110 that is a surface on which the semiconductor element is mounted, and on the upper surface 110a of the first wiring structure 110, the electrode pads 111 are exposed from the first thin film layer 112. The electrode pads 111 are connected to the wiring layer 116 of the second thin film layer 113 by the vias 117 that penetrate the insulating layer 110c of the first thin film layer 112.

The electronic component 130 is embedded in the first thin film layer 112 and the second thin film layer 113. A cavity for housing therein the electronic component 130 is formed in the first thin film layer 112 and the second thin film layer 113.

In an electronic component embedding process to be mentioned later, the filling resin layer 114 is a layer that is continuously formed with a filling resin 135 filling the cavity. On a surface of the filling resin layer 114, the wiring layer 116 including wirings 116a is formed. The wirings 116a serve as transmission wirings for transmitting an input/output signal of the electronic component 130. The vias 117 are formed in the filling resin layer 114 after the electronic component embedding process, and the wiring layer 116 on the surface of the filling resin layer 114 is connected to the wiring layer 116 on a surface of the second thin film layer 113 or electrodes 131 of the electronic component 130.

The electronic component 130 is an electronic component such as a capacitor, and has the function for reducing noise from the semiconductor element mounted on the upper surface 110a of the first wiring structure 110. For example, an electronic component other than a capacitor, such as an inductor and a semiconductor element may be used as the electronic component 130. The electronic component 130 is embedded in the first thin film layer 112 and the second thin film layer 113. In other words, the filling resin 135 fills a periphery of the electronic component 130 so that the electronic component 130 is embedded in the first wiring structure 110.

As described above, in the embodiment, the electronic component 130 is embedded in the first wiring structure 110, and therefore a semiconductor element mounted on the upper surface 110a of the first wiring structure 110 is connected to the electronic component 130 via the wirings alone of the first wiring board 100 that is the relay board. In other words, the semiconductor element and the electronic component 130 are connected to each other via the electrode pads 111, the wiring layer 116, the vias 117, and the wirings 116a of the wiring layer 116 in the first wiring board 100. Thus, compared with a structure in which a semiconductor element is connected to an electronic component mounted on a main board via wirings of a relay board and wirings of the main board, it is possible to reduce a length of the wirings between the semiconductor element and the electronic component 130 to be able to reduce an inductance of the above-mentioned wirings. As a result, noise from the semiconductor element can be effectively reduced in the electronic component 130, so that it is possible to reduce diffusion of noise from the semiconductor element.

Furthermore, in the embodiment, a thickness of the first wiring structure 110 is equal to or less than a thickness of the second wiring structure 120. Hence, it is possible to facilitate further thinning of the first wiring board 100.

Furthermore, in the embodiment, the first wiring structure 110 is formed on the glass support member 300 in a state where the upper surface 110a, which is a mounting surface of the semiconductor element, faces the glass support member 300. Thus, strength of the first wiring board 100 is increased so as to improve a handling ability of the first wiring board 100.

The second wiring structure 120 is a structure having a thickness of approximately 50 μm to 100 μm, for example, which is configured by forming the electrode pads 121 on a reinforcing insulating layer 123. The reinforcing insulating layer 123 is formed by impregnating a reinforcing member such as a glass fiber with an insulation resin material. The reinforcing insulating layer 123 includes the reinforcing member, and thus the rigidity of the second wiring structure 120 is greater than the rigidity of the first wiring structure 110 so as to improve the strength of the first wiring board 100. A reinforcing member other than glass fiber, such as carbon fiber, may be used as a reinforcing member for the reinforcing insulating layer 123. The insulation resin material, with which the reinforcing member of the reinforcing insulating layer 123 is to be impregnated, is a resin that is cured by thermosetting, such as an epoxy resin and a polyimide resin. The electrode pads 121 are formed on a surface of the reinforcing insulating layer 123. The electrode pads 121 are formed of a conductor such as copper, and are used as connection terminals in a case where the first wiring board 100 is bonded to the second wiring board 200. The electrode pads 121 are connected to wirings of the first wiring structure 110 by the vias 122 that penetrate through the reinforcing insulating layer 123. The vias 122 are formed in a truncated cone shape whose diameter on a side of the electrode pads 111 is smaller than that on a side of the electrode pads 121.

Note that the first wiring board 100 and the second wiring board 200 are bonded to each other, and then the glass support member 300 illustrated in FIG. 2 is peeled off from the first wiring board 100; however, the timing of peeling off the glass support member 300 is not limited thereto. For example, the glass support member 300 may be peeled off at the step where the first wiring board 100 is manufactured on the glass support member 300 illustrated in FIG. 2.

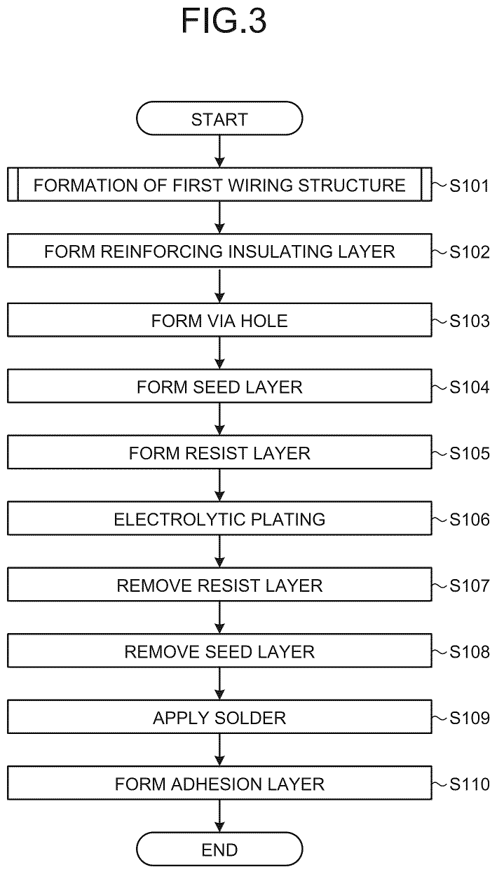

Next, with reference to a flowchart illustrated in FIG. 3, a manufacturing method of the first wiring board 100 illustrated in FIG. 2 will be specifically explained. FIG. 3 is a flowchart illustrating a manufacturing method of the first wiring board 100 according to the embodiment.

First, on the glass support member 300, the first wiring structure 110 is formed in a state where the upper surface 110a of the first wiring structure 110 faces the glass support member (Step S101). In other words, the first thin film layer 112, the second thin film layer 113, the filling resin layer 114, and the third thin film layer 115 are sequentially laminated on the glass support member 300 so as to form the first wiring structure 110 that includes the wiring layers 116 including minute wirings and in which the electronic component 130 is embedded. Details of a forming process of the first wiring structure 110 will be described later.

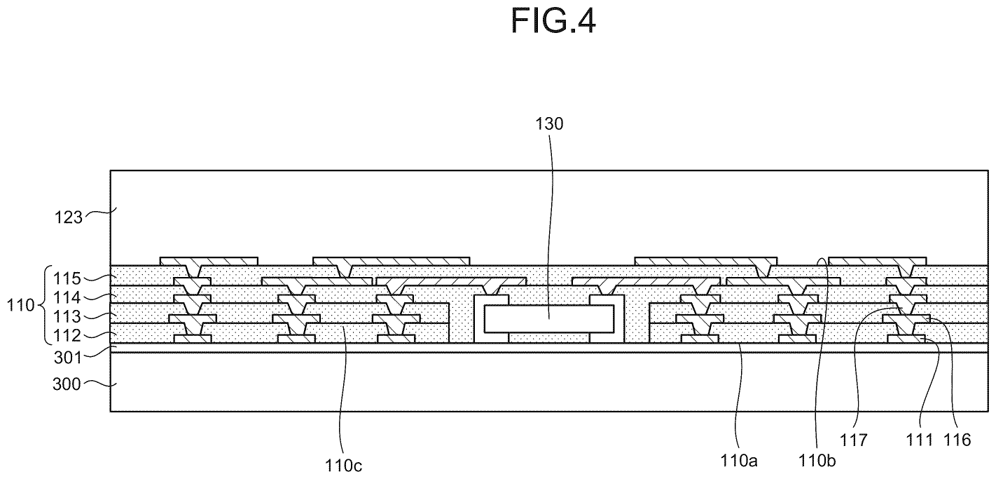

In a case where the first wiring structure 110 is formed, the reinforcing insulating layer 123 covering the outermost layer of the wiring layer 116 of the first wiring structure 110 is formed on the lower surface 110b of the first wiring structure 110 (Step S102). In other words, for example, as illustrated in FIG. 4, the reinforcing insulating layer 123 in an uncured state is laminated on the lower surface 110b of the first wiring structure 110 so that the wiring layer 116 is covered by the reinforcing insulating layer 123. The reinforcing insulating layer 123 formed on the lower surface 110b of the first wiring structure 110 is cured by thermosetting. FIG. 4 is a diagram illustrating a specific example of a reinforcing insulating layer forming process.

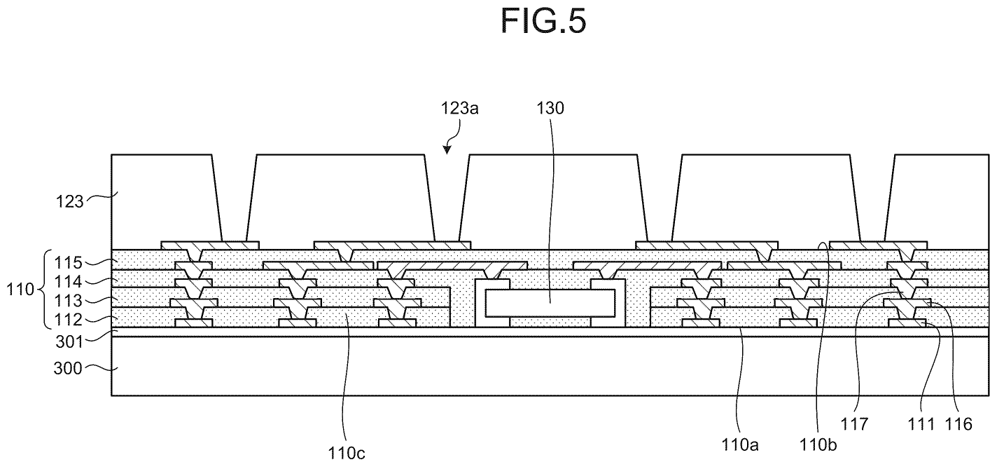

Next, via holes are formed in the reinforcing insulating layer 123 (Step S103). Specifically, for example, as illustrated in FIG. 5, via holes 123a are formed which penetrate through the reinforcing insulating layer 123 so as to expose a surface of the wiring layer 116 of the outermost layer of in the first wiring structure 110. FIG. 5 is a diagram illustrating a specific example of a via hole forming process. The via holes 123a may be formed by laser machining, for example. Residue (smear) of the insulation resin material generated by the laser machining is removed by desmear processing.

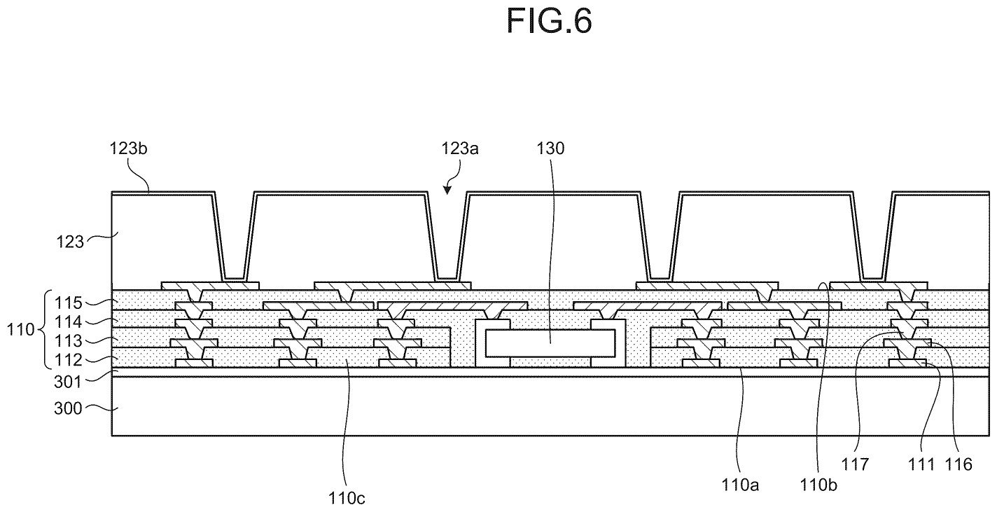

In a case where the via holes 123a are formed, a seed layer is formed on a surface of the reinforcing insulating layer 123 by sputtering of copper, for example (Step S104). In other words, for example, as illustrated in FIG. 6, a seed layer 123b is formed, which covers a surface of the wiring layer 116 exposed at the via holes 123a, and a surface of the reinforcing insulating layer 123 including inner walls of the via holes 123a. FIG. 6 is a diagram illustrating a specific example of a seed layer forming process.

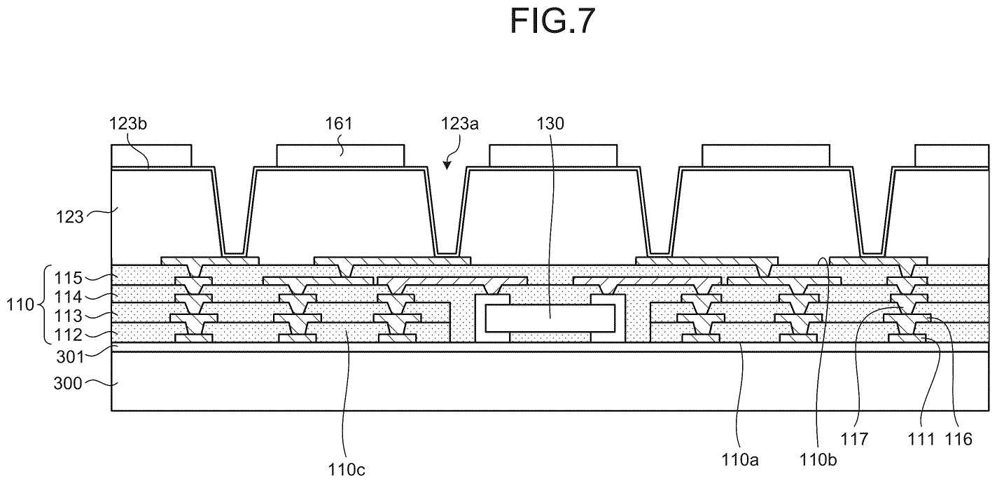

In a case where the seed layer 123b is formed, a resist layer for forming the electrode pads 121 and the vias 122 is formed on the seed layer 123b (Step S105). In other words, for example, as illustrated in FIG. 7, a resist layer 161 is formed on the seed layer 123b by patterning with the use of exposure/development, which includes openings corresponding to formed positions of the electrode pads 121 and the vias 122. FIG. 7 is a diagram illustrating a specific example of a resist layer forming process.

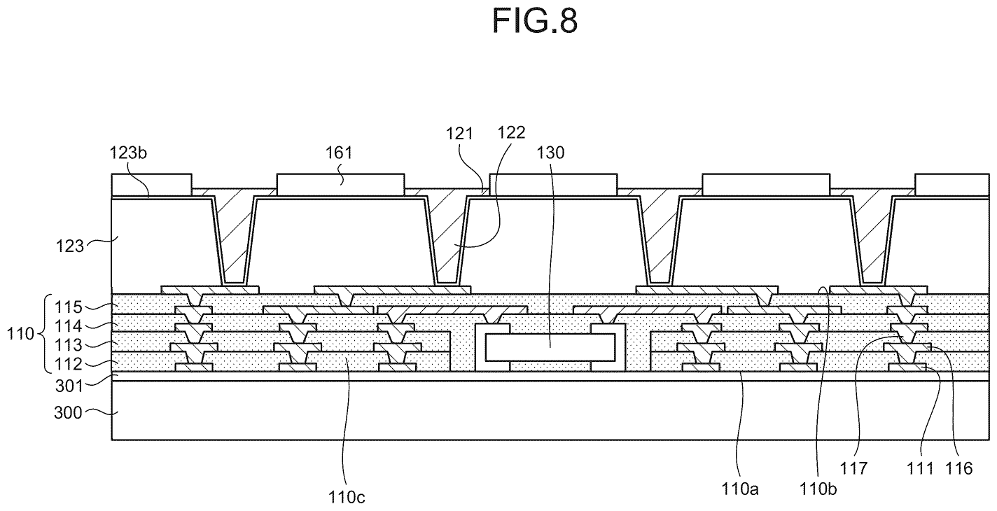

In a case where the resist layer 161 is formed, the electrode pads 121 and the vias 122 are formed on the seed layer 123b, which is exposed from the openings of the resist layer 161, by electrolytic copper plating whose power is supplied from the seed layer 123b, for example (Step S106). Specifically, for example, as illustrated in FIG. 8, the via holes 123a are filled with electrolytic copper plating so as to form the vias 122, and further the electrode pads 121 are formed in an upper side of the vias 122. FIG. 8 is a diagram illustrating of a specific example of an electrolytic copper plating process.

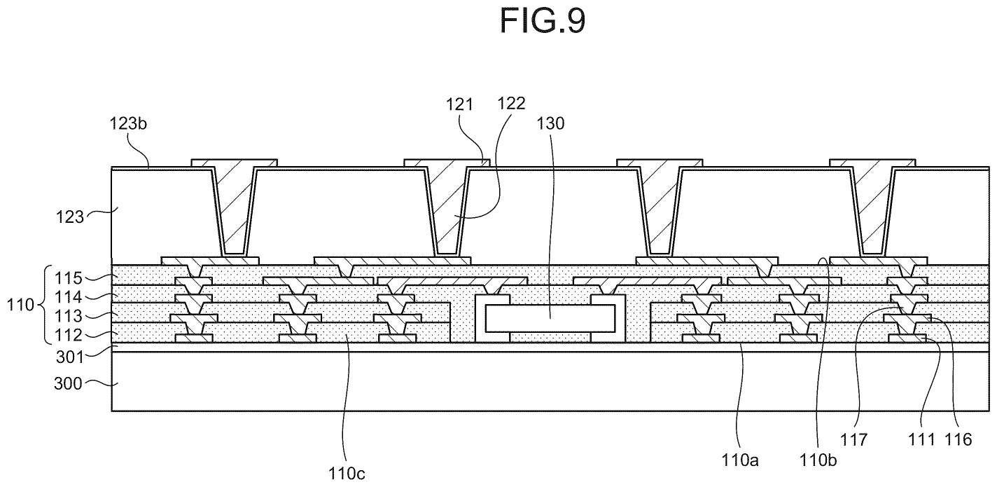

In a case where the electrode pads 121 and the vias 122 are formed by electrolytic copper plating, for example, as illustrated in FIG. 9, the resist layer 161 is removed (Step S107). FIG. 9 is a diagram illustrating a specific example of a resist layer removing process. Sodium hydroxide or amine-based alkaline peeling liquid is used in removing the resist layer 161, for example.

In a case where the resist layer 161 is removed, an unnecessary part of the seed layer 123b is removed by flash etching (Step S108) so as to complete the second wiring structure 120. Specifically, the seed layer 123b is removed which is exposed without being in contact with the electrode pads 121 and the vias 122 so that the reinforcing insulating layer 123 is exposed in other than parts being in contact with the electrode pads 121 and the vias 122. Note that the seed layer 123b being in contact with the electrode pads 121 and the vias 122 remains after flash etching; however, illustration thereof is omitted in the subsequent drawings.

In a case where the second wiring structure 120 is completed, an intermediate structure illustrated in FIG. 2 is obtained. In other words, an intermediate structure is formed, in which the first wiring structure 110 and the second wiring structure 120 are formed on the glass support member 300. The first wiring structure 110 and the second wiring structure 120 constitute the first wiring structure 110.

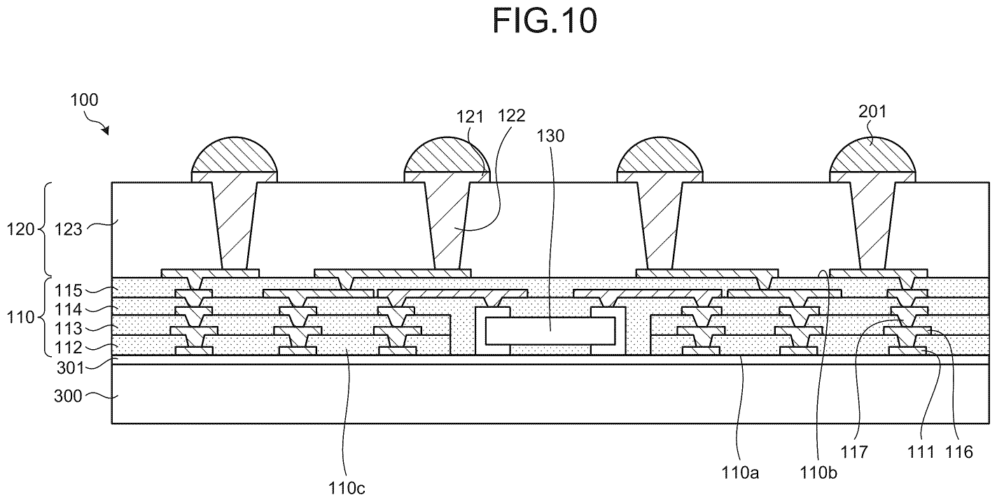

Subsequently, for example, as illustrated in FIG. 10, the solder 201 is applied to the electrode pads 121 of the first wiring board 100 so as to bond the first wiring board 100 to the second wiring board 200 (Step S109). FIG. 10 is a diagram illustrating a specific example of a solder applying process.

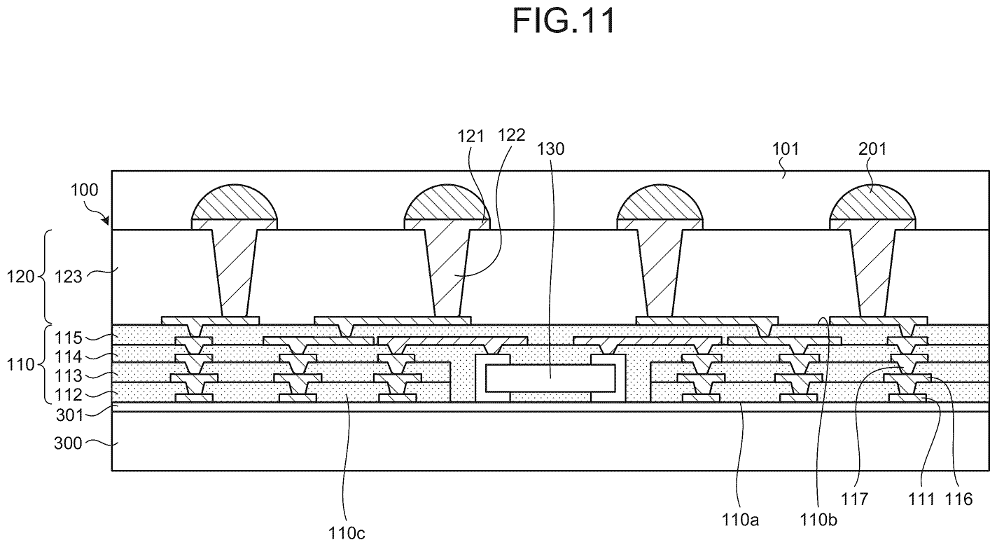

In a case where the solder 201 is applied to the electrode pads 121 of the first wiring board 100, for example, as illustrated in FIG. 11, the adhesion layer 101 covering the electrode pads 121 and the solder 201 is formed on a lower surface of the second wiring structure 120 where the electrode pads 121 locate (Step S110). FIG. 11 is a diagram illustrating a specific example of an adhesion layer forming process.

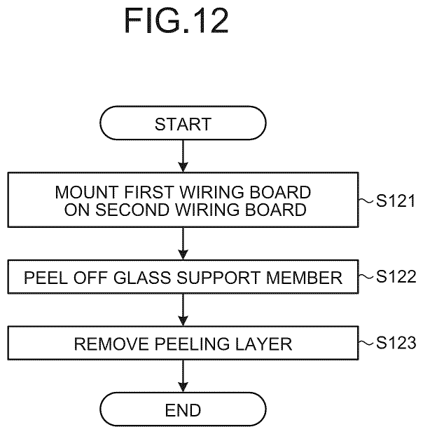

Next, with reference to a flowchart illustrated in FIG. 12, a manufacturing method of the board illustrated in FIG. 1 will be specifically explained. FIG. 12 is a flowchart illustrating a manufacturing method of the board according to the embodiment.

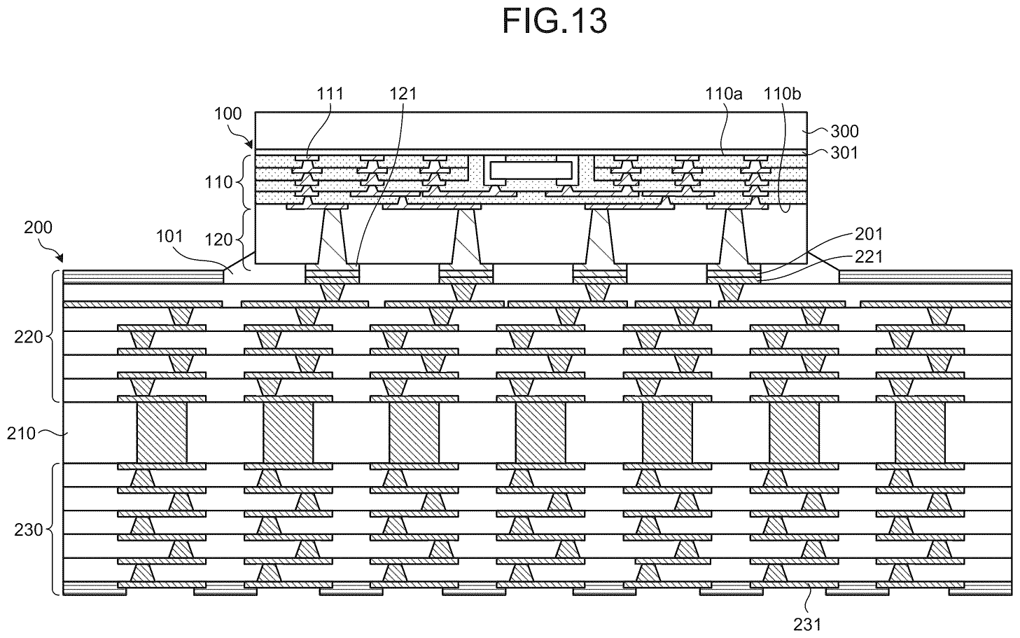

First, the first wiring board 100 manufactured on the glass support member 300 is mounted on the second wiring board 200 via the adhesion layer 101 (Step S121). Specifically, for example, as illustrated in FIG. 13, the first wiring board 100 and the second wiring board 200 are bonded to each other by the adhesion layer 101 so that the electrode pads 121 of the first wiring board 100 and the electrode pads 221 of the second wiring board 200 are connected to each other via the solder 201. FIG. 13 is a diagram illustrating a specific example of a first wiring board mounting process.

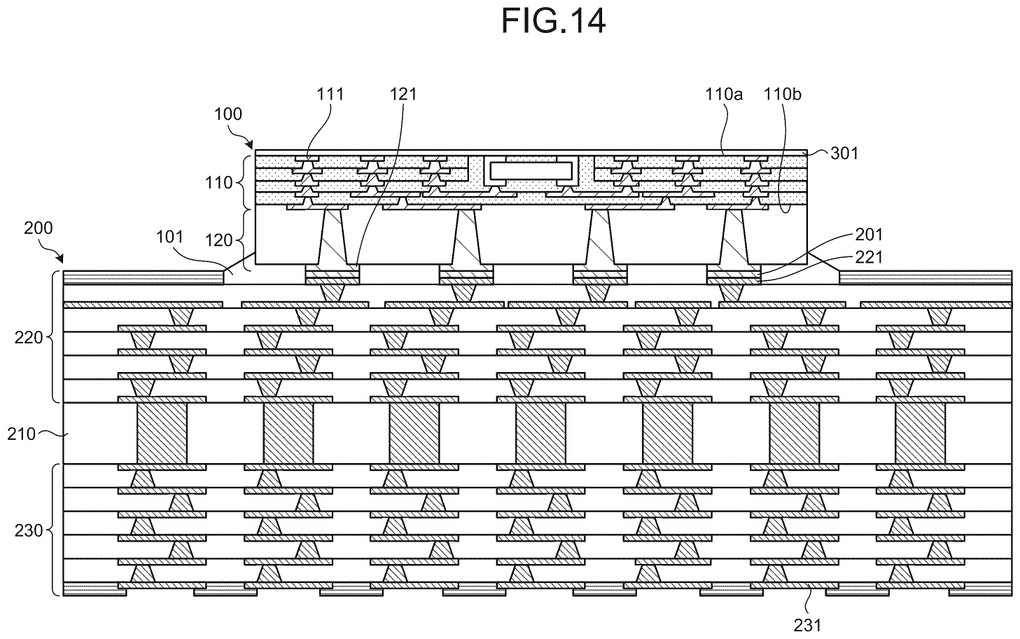

In a case where the first wiring board 100 and the second wiring board 200 are bonded to each other by the adhesion layer 101 and the solder 201, for example, as illustrated in FIG. 14, the glass support member 300 is peeled off from the peeling layer 301 of the first wiring board 100 (Step S122). FIG. 14 is a diagram illustrating a specific example of a glass support member peeling process.

Next, the peeling layer 301 is removed (Step S123) whereby the laminated wiring board illustrated in FIG. 1 is completed, which is obtained by laminating the first wiring board 100 on the second wiring board 200.

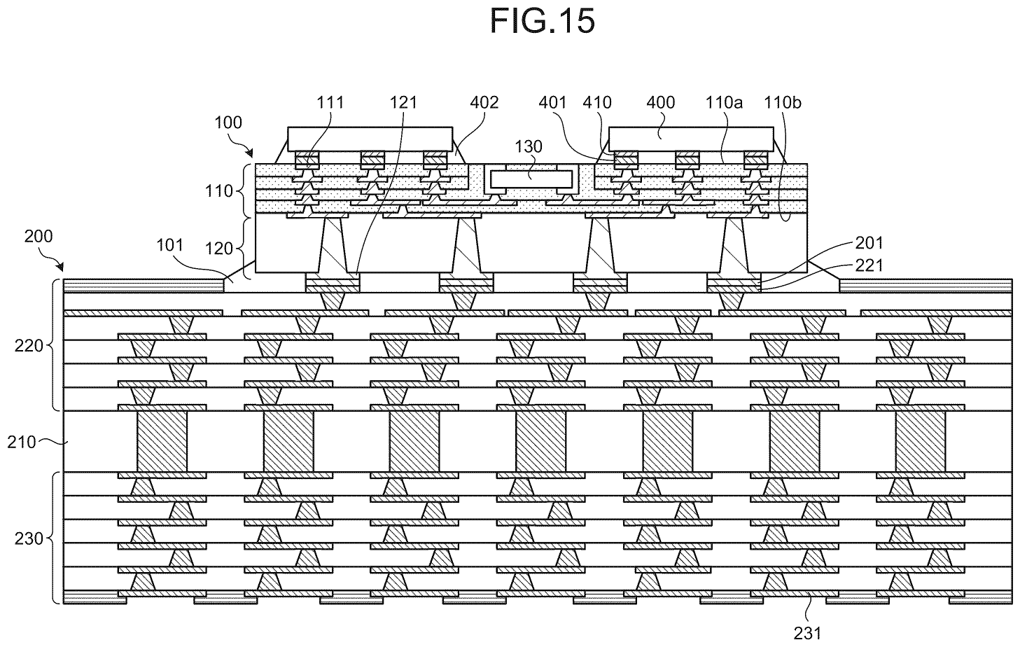

The laminated wiring board illustrated in FIG. 1 may be used in a semiconductor device on which a semiconductor element such as a semiconductor chip is mounted. Specifically, for example, as illustrated in FIG. 15, a semiconductor chip 400 is mounted on the upper surface 110a of the first wiring board 100. FIG. 15 is a diagram illustrating a configuration example of the semiconductor device. Electrodes 410 of the semiconductor chip 400 and the electrode pads 111 of the first wiring board 100 are bonded to each other by solder 401. Connection portions between the electrodes 410 and the electrode pads 111 are sealed with an underfill resin 402. Thus, the semiconductor device is obtained in which the semiconductor chip 400 is mounted, via the underfill resin 402, on the first wiring board 100 that is the relay board.

In the above-mentioned semiconductor device, the electronic component 130 is embedded in the first wiring structure 110. Therefore, the semiconductor chip 400 mounted on the upper surface 110a of the first wiring structure 110 is connected to the electronic component 130 via the wirings alone of the first wiring board 100 that is the relay board. In other words, the semiconductor chip 400 is connected to the electronic component 130 via the electrode pads 111, the wiring layers 116, the vias 117, and the wirings 116a of the wiring layers 116 in the first wiring board 100. Thus, compared with a structure in which the semiconductor chip 400 is connected to the electronic component mounted on the main board via wirings of the relay board and wirings of the main board, it is possible to reduce a length of the wirings between the semiconductor chip 400 and the electronic component 130 to be able to reduce an inductance of the above-mentioned wirings. As a result, noise from the semiconductor chip 400 can be effectively reduced in the electronic component 130, so that it is possible to reduce diffusion of noise from the semiconductor chip 400.

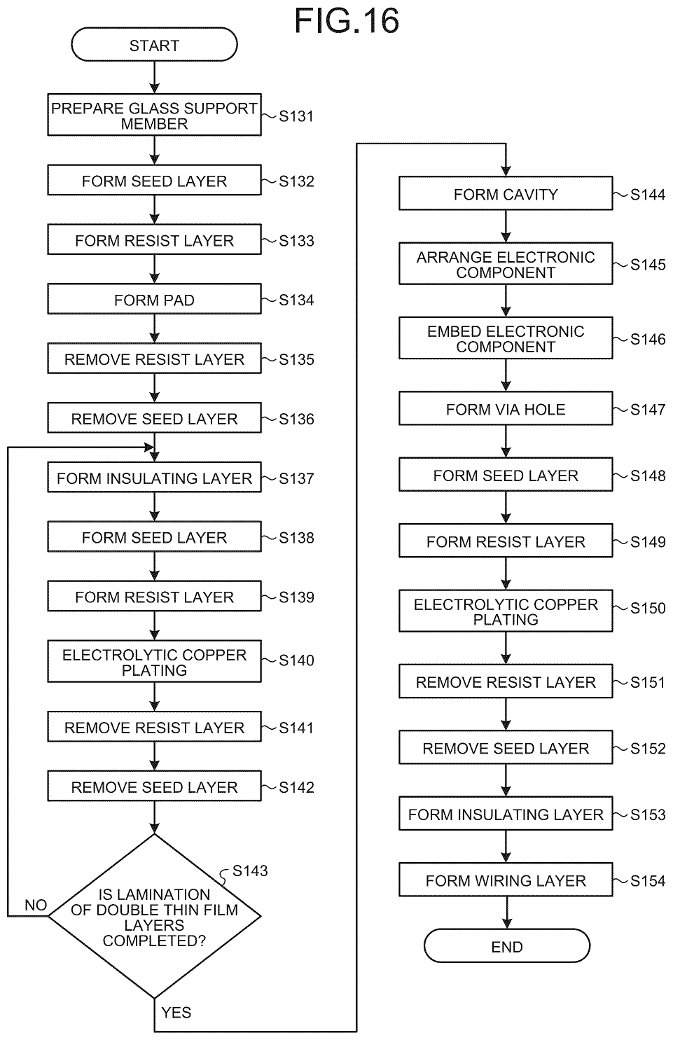

Next, with reference to a flowchart illustrated in FIG. 16, a forming process of the first wiring structure 110 of the first wiring board 100 will be specifically explained. FIG. 16 is a flowchart illustrating a forming method of the first wiring structure 110 according to the embodiment. The forming process of the first wiring structure 110 illustrated in FIG. 16 corresponds to Step S101 illustrated in FIG. 3.

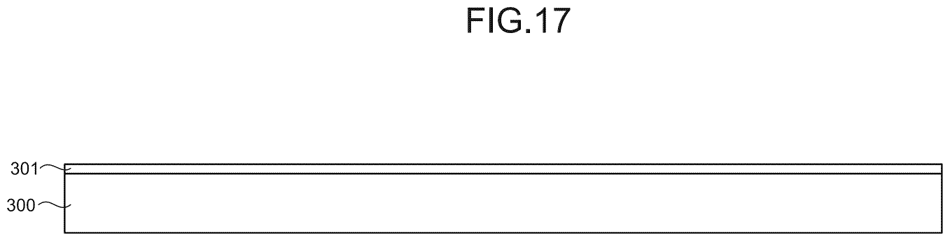

First, the glass support member 300 is prepared, which serves as a support member in manufacturing the first wiring board 100 (Step S131). Specifically, for example, as illustrated in FIG. 17, the peeling layer 301 is formed on a flat upper surface of the glass support member 300. FIG. 17 is a diagram illustrating a specific example of the glass support member 300. A silicone-based or acrylic adhesive material is used as the peeling layer 301, for example.

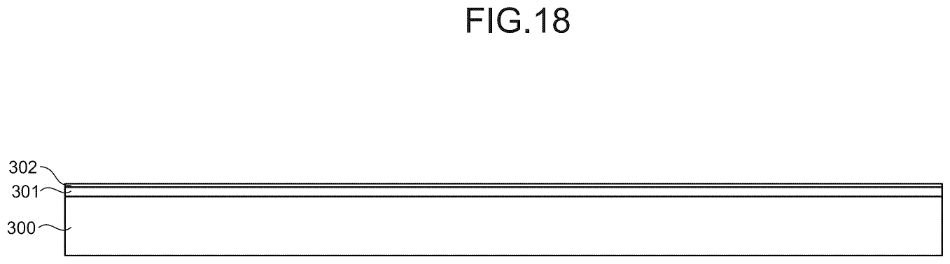

Next, for example, as illustrated in FIG. 18, a seed layer 302 is formed on an upper surface of the peeling layer 301 of the glass support member 300 by sputtering of copper, for example, (Step S132). FIG. 18 is a diagram illustrating a specific example of the seed layer forming process.

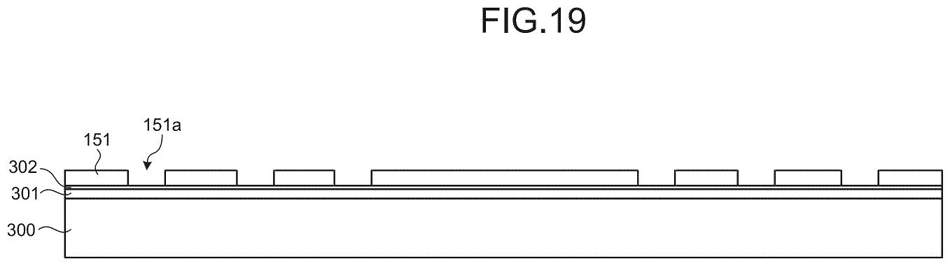

Next, for example, as illustrate in FIG. 19, a resist layer 151 is formed, which includes openings 151a on the seed layer 302 (Step S133). The resist layer 151 is formed by using dry film resist, for example, and the openings 151a may be formed by using photolithography or laser machining, for example. FIG. 19 is a diagram illustrating a specific example of the resist layer forming process.

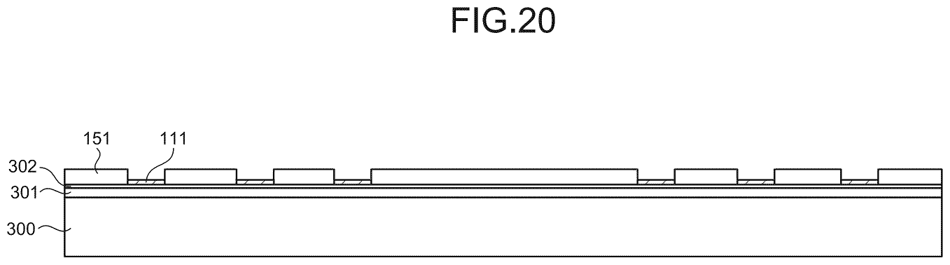

In a case where the resist layer 151 is formed, the electrode pads 111 are formed by electrolytic copper plating whose power is supplied from the seed layer 302 (Step S134). Specifically, for example, as illustrated in FIG. 20, the electrode pads 111 are formed on the seed layer 302 that is exposed at the openings 151a of the resist layer 151. FIG. 20 is a diagram illustrating a specific example of an electrode pad forming process.

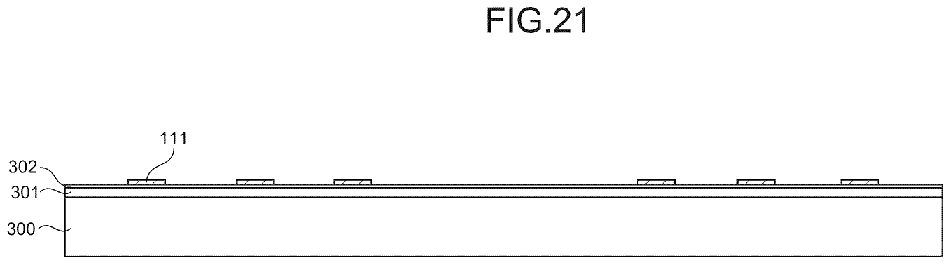

Subsequently, as illustrated in FIG. 21, the resist layer 151 is removed (Step S135), for example. FIG. 21 is a diagram illustrating a specific example of a resist layer removing process. For example, sodium hydroxide and/or amine-based alkaline peeling liquid is used in removing the resist layer 151.

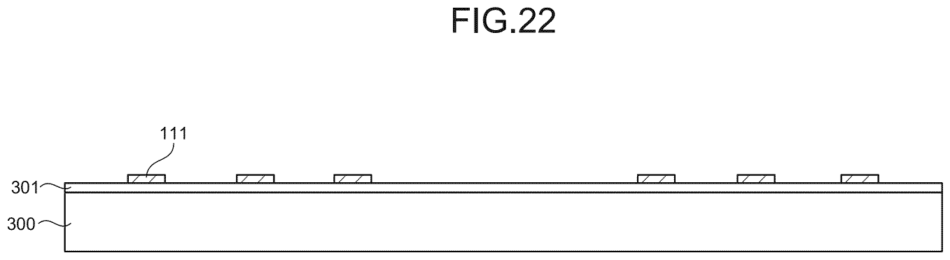

In a case where the resist layer 151 is removed, an unnecessary portion of the seed layer 302 is removed by flash etching (Step S136). Specifically, etchant for dissolving the seed layer 302 dissolves the seed layer 302 that is exposed without being in contact with the electrode pads 111, for example, and as illustrated in FIG. 22, the peeling layer 301 is exposed in other than the part being in contact with the electrode pads 111. FIG. 22 is a diagram illustrating a specific example of a seed layer removing process. Note that the seed layer 302 being in contact with the electrode pads 111 remains after flash etching; however, illustration thereof is omitted in FIG. 22.

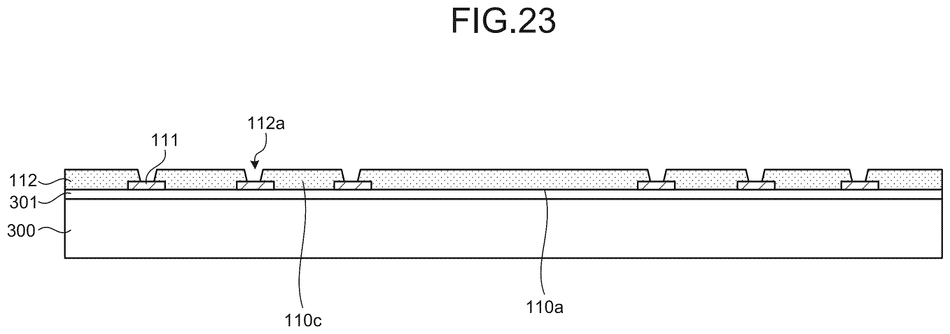

In a case where the seed layer 302 is removed, the first wiring structure 110 is formed on the peeling layer 301. The insulating layer 110c of the first thin film layer 112 is formed on the peeling layer 301 so as to cover the electrode pads 111 (Step S137). The insulating layer 110c is formed by using a photosensitive insulation resin material, and via holes are formed by photolithography. Specifically, for example, as illustrated in FIG. 23, in positions corresponding to the electrode pads 111, via holes 112a are formed on the insulating layer 110c of the first thin film layer 112, which expose upper surfaces of the electrode pads 111. FIG. 23 is a diagram illustrating a specific example of an insulating layer forming process. A surface (lower surface) of the first thin film layer 112, which is located on an upper side of the glass support member 300, forms the upper surface 110a of the first wiring structure 110 that is a mounting surface for a semiconductor element, and in the above-mentioned upper surface 110a of the first wiring structure 110, the electrode pads 111 are exposed from the first thin film layer 112.

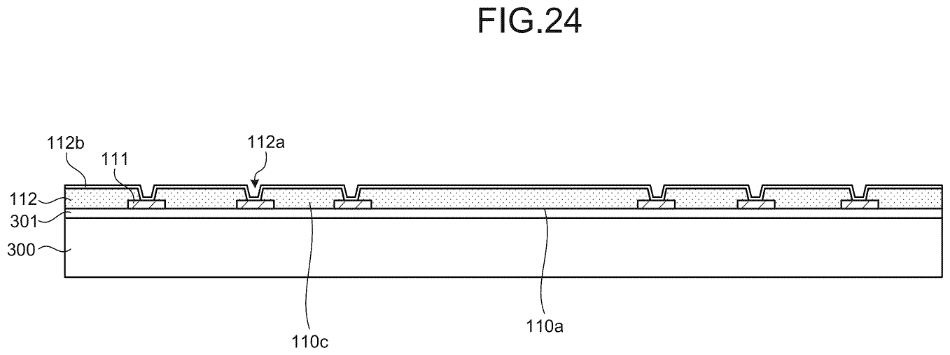

Next, a seed layer is formed on a surface of the insulating layer 110c of the first thin film layer 112 by sputtering of copper, for example (Step S138). In other words, for example, as illustrated in FIG. 24, a seed layer 112b is formed, which covers surfaces of the electrode pads 111 that are exposed at the via holes 112a, and a surface of the insulating layer 110c of the first thin film layer 112 including inner walls of the via holes 112a. FIG. 24 is a diagram illustrating a specific example of the seed layer forming process.

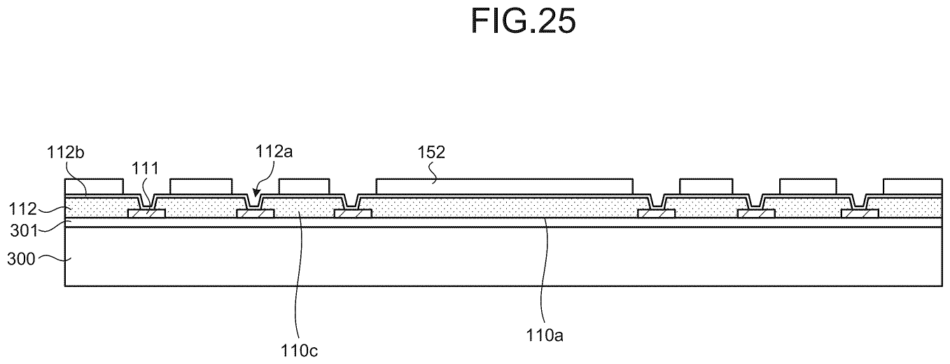

In a case where the seed layer 112b is formed, a resist layer is formed on the seed layer 112b, which is for forming the wiring layers 116 of the first thin film layer 112 (Step S139). In other words, for example, as illustrated in FIG. 25, a resist layer 152 is formed on the seed layer 112b by patterning with the use of exposure/development, which includes openings corresponding to wiring pattern formed parts of minute wirings. FIG. 25 is a diagram illustrating a specific example of the resist layer forming process.

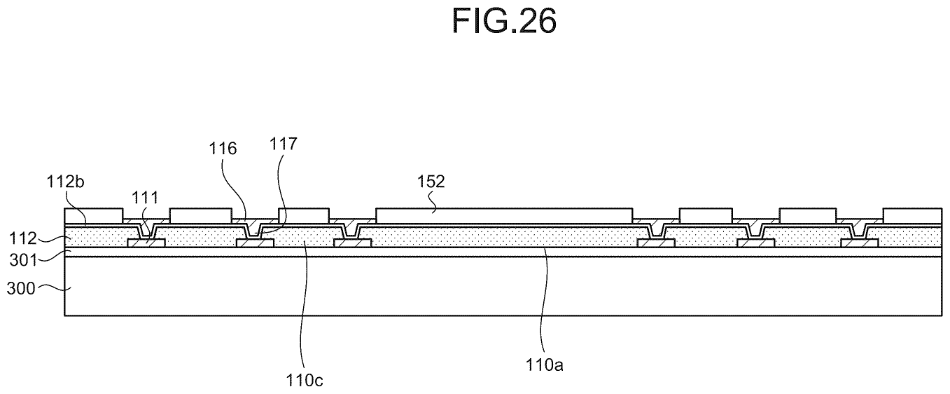

In a case where the resist layer 152 is formed, the wiring layer 116 and the vias 117 of the first thin film layer 112 are formed on the seed layer 112b that is exposed from openings of the resist layer 152 by electrolytic copper plating whose power is supplied from the seed layer 112b, for example (Step S140). Specifically, for example, as illustrated in FIG. 26, the via holes 112a are filled with electrolytic copper so as to form the vias 117, and further the wiring layer 116 including minute wirings is formed. FIG. 26 is a diagram illustrating a specific example of the electrolytic copper plating process.

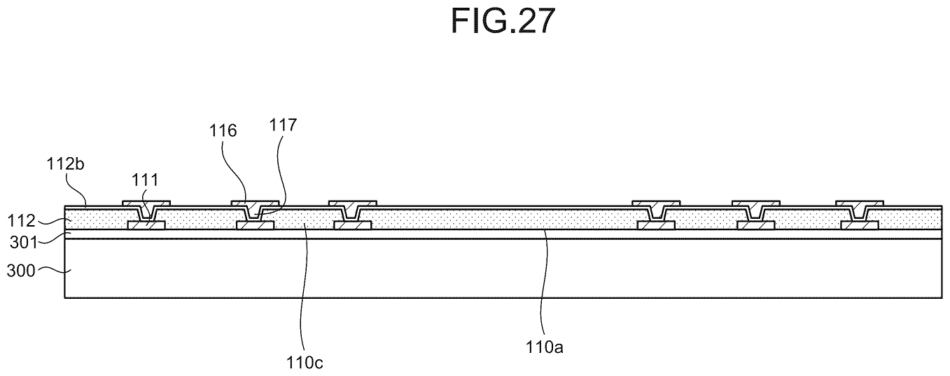

In a case where the wiring layer 116 and the vias 117 of the first thin film layer 112 are formed by electrolytic copper plating, for example, as illustrated in FIG. 27, the resist layer 152 is removed (Step S141). FIG. 27 is a diagram illustrating a specific example of the resist layer removing process. Sodium hydroxide and/or amine-based alkaline peeling liquid is used in removing the resist layer 152, for example.

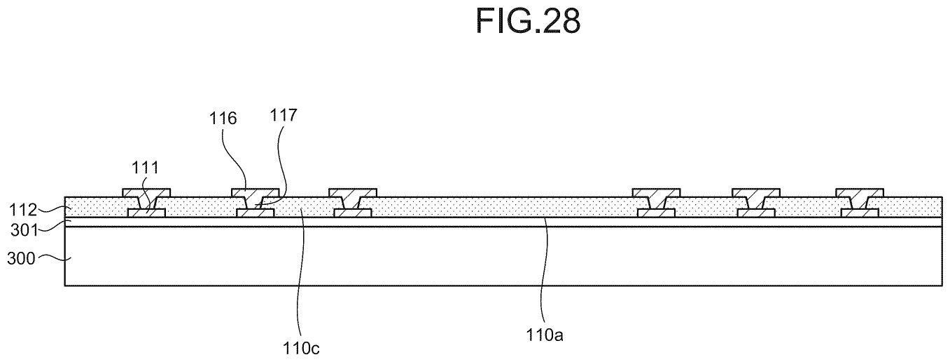

In a case where the resist layer 152 is removed, an unnecessary portion of the seed layer 112b is removed by flash etching (Step S142) so as to complete formation of the first thin film layer 112 of the first wiring structure 110. In other words, for example, as illustrated in FIG. 28, the seed layer 112b other than a part being in contact with the wiring layer 116 and the vias 117 is removed, and the first thin film layer 112 including the insulating layer 110c, the wiring layer 116, and the vias 117 is laminated on the peeling layer 301. FIG. 28 is a diagram illustrating a specific example of the seed layer removing process. Note that the seed layer 112b being in contact with the wiring layer 116 and the vias 117 remain after flash etching; however, illustration thereof is omitted in FIG. 28.

A plurality of thin film layers, which constitute the first wiring structure 110, may be laminated, and thus whether or not lamination of double thin film layers (namely, first thin film layer 112 and second thin film layer 113), in which the electronic component 130 is to be embedded, is completed is determined (Step S143). In a case where the lamination of double thin film layers is not completed (Step S143: No), a process similar to the above-mentioned formation of the first thin film layer 112 is repeated so as to form the second thin film layer 113.

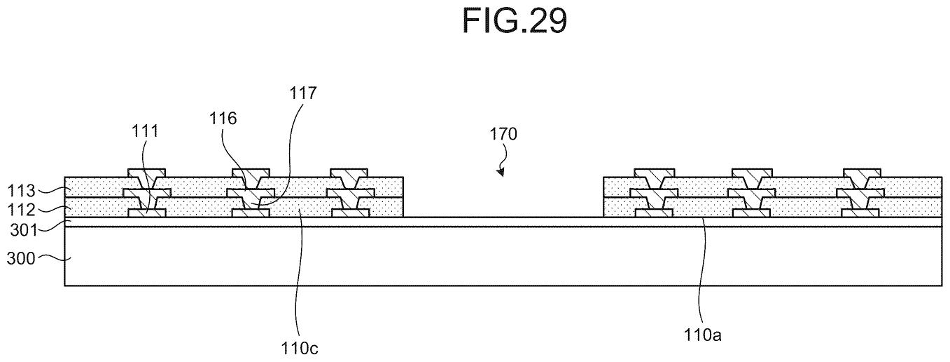

On the other hand, in a case where lamination of double thin film layers is completed (Step S143: Yes), a cavity is formed in a region in which the electronic component 130 is to be housed (Step S144). Specifically, for example, as illustrated in FIG. 29, the insulating layers 110c of the first thin film layer 112 and the second thin film layer 113 are cut out in a direction toward a surface (namely, upper surface 110a to be mounting surface of semiconductor element) of the first thin film layer 112 located on an upper side of the glass support member 300 so as to form a cavity 170. FIG. 29 is a diagram illustrating a specific example of a cavity forming process. The cavity forming process can be realized by performing laser machining with the use of CO2 laser, for example. The insulating layers 110c of the first thin film layer 112 and the second thin film layer 113 are cut out up to a surface (namely, upper surface 110a to be mounting surface of semiconductor element) of the first thin film layer 112 located on an upper side of the glass support member 300, and thus the peeling layer 301 is exposed at a bottom surface of the cavity 170.

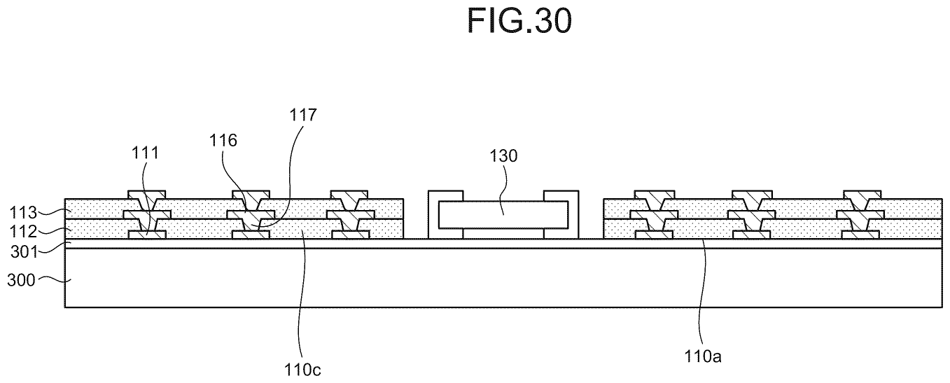

Next, the electronic component 130 is arranged in the cavity 170 (Step S145). Specifically, for example, as illustrated in FIG. 30, the electronic component 130 is temporarily bonded to the peeling layer 301 in the cavity 170. FIG. 30 is a diagram illustrating a specific example of an electronic component arranging process.

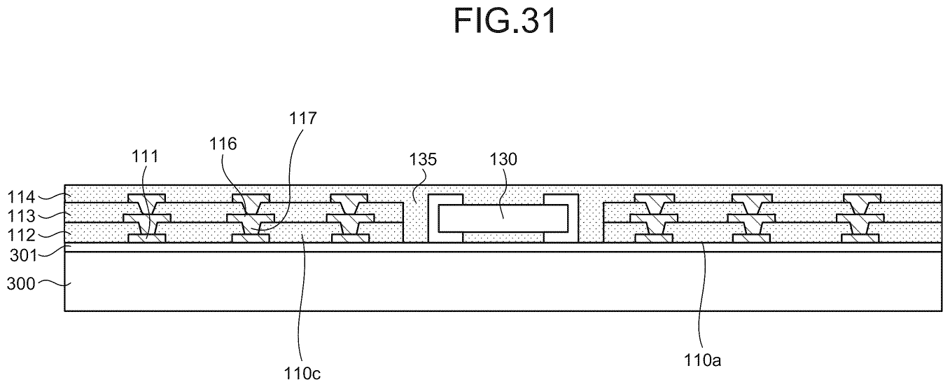

In a case where the electronic component 130 is arranged in the cavity 170, the cavity 170 is filled with the filling resin 135 so that the electronic component 130 is embedded (Step S146). In other words, for example, as illustrated in FIG. 31, the cavity 170 is filled with the filling resin 135, and further the filling resin layer 114 extending over the electronic component 130 is formed. Thus, the electronic component 130 is embedded in the first thin film layer 112 and the second thin film layer 113. FIG. 31 is a diagram illustrating a specific example of an electronic component embedding process. In a case where the cavity 170 is filled with the filling resin 135 so as to form the filling resin layer 114, thermosetting is performed on the above-mentioned resin, and the electronic component 130 is fixed onto the peeling layer 301 in the cavity 170. The peeling layer 301 is to be finally removed in manufacturing the board illustrated in FIG. 1 (see Step S123 illustrated in FIG. 12), the electronic component 130 having been fixed onto the peeling layer 301 is exposed at the upper surface 110a of the first wiring structure 110 by removal of the peeling layer 301. The electronic component 130 is exposed at the upper surface 110a of the first wiring structure 110, and thus heat generated from the electronic component 130 is effectively radiated to the outside of the first wiring structure 110.

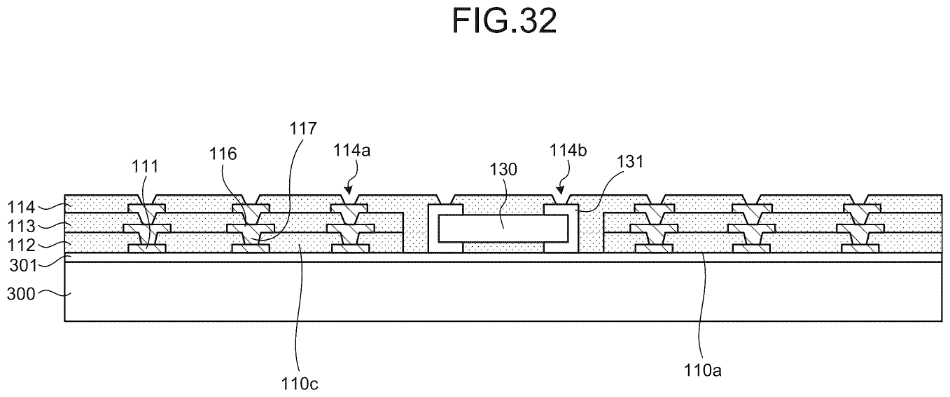

After the electronic component 130 is embedded, via holes are formed in the filling resin layer 114 (Step S147). Specifically, for example, as illustrated in FIG. 32, there are formed via holes 114a, each of which penetrates through the filling resin layer 114 so as to expose the wiring layer 116 of the second thin film layer 113, and via holes 114b, each of which penetrates through the filling resin layer 114 so as to expose the corresponding electrode 131 of the electronic component 130. FIG. 32 is a diagram illustrating a specific example of a via hole forming process. The via holes 114a and 114b may be formed by laser machining, or photolithography, for example.

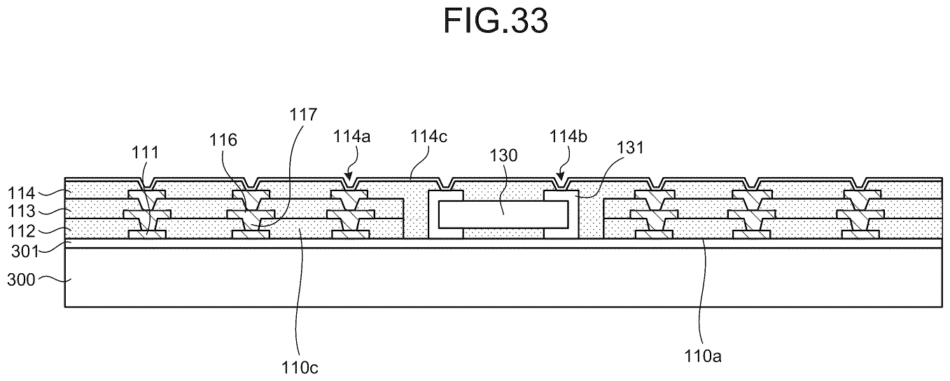

Next, a seed layer is formed on a surface of the filling resin layer 114 by sputtering of copper, for example (Step S148). In other words, for example, as illustrated in FIG. 33, a seed layer 114c is formed that covers a surface of the wiring layer 116 being exposed at the via holes 114a, inner walls of the via holes 114a, surfaces of the electrodes 131 being exposed at the via holes 114b, and a surface of the filling resin layer 114 including inner walls of the via holes 114b. FIG. 33 is a diagram illustrating a specific example of the seed layer forming process.

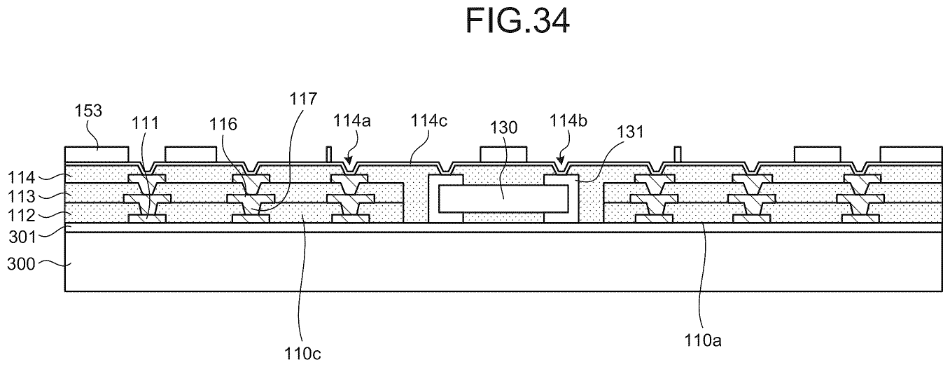

In a case where the seed layer 114c is formed, a resist layer is formed on the seed layer 114c, which is for forming the wiring layer 116 of the filling resin layer 114 (Step S149). In other words, for example, as illustrated in FIG. 34, a resist layer 153 is formed on the seed layer 114c by patterning with the use of exposure/development, which includes openings corresponding to wiring pattern formed parts of minute wirings. FIG. 34 is a diagram illustrating a specific example of the resist layer forming process.

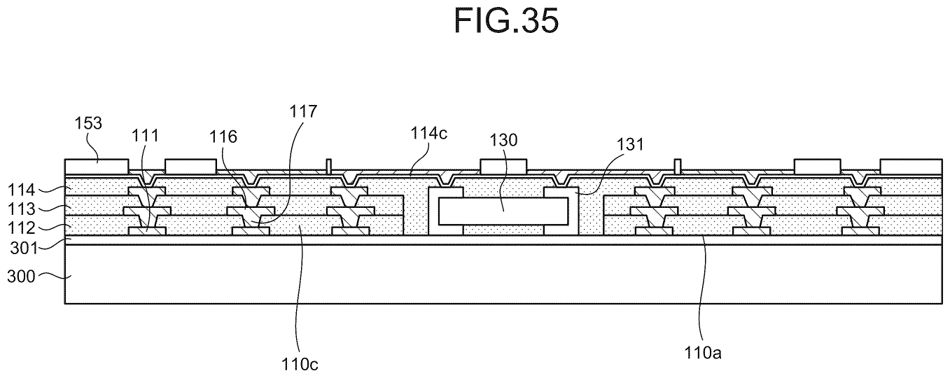

In a case where the resist layer 153 is formed, the wiring layer 116 and the vias 117 of the filling resin layer 114 are formed on the seed layer 114c that is exposed from openings of the resist layer 153 by electrolytic copper plating whose power is supplied from the seed layer 114c, for example (Step S150). Specifically, for example, as illustrated in FIG. 35, the via holes 114a and 114b are filled with electrolytic copper so as to form the vias 117, and further the wiring layer 116 including minute wirings is formed. FIG. 35 is a diagram illustrating a specific example of the electrolytic copper plating process.

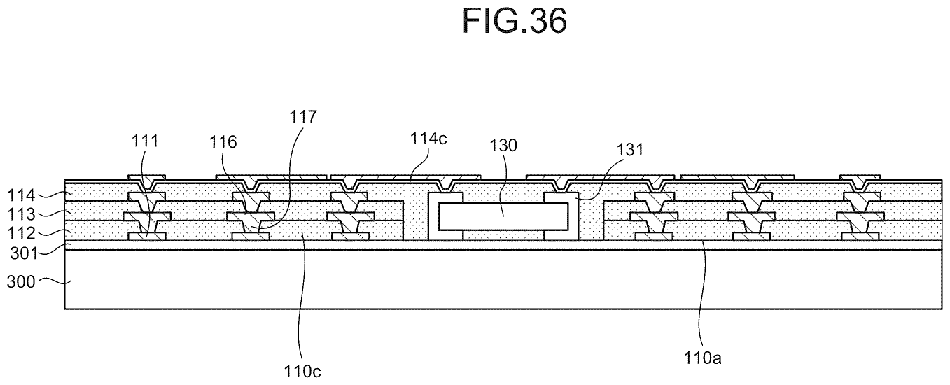

In a case where the wiring layer 116 and the vias 117 of the filling resin layer 114 are formed by electrolytic copper plating, for example, as illustrated in FIG. 36, the resist layer 153 is removed (Step S151). FIG. 36 is a diagram illustrating a specific example of the resist layer removing process. Sodium hydroxide and/or amine-based alkaline peeling liquid is used in removing the resist layer 153, for example.

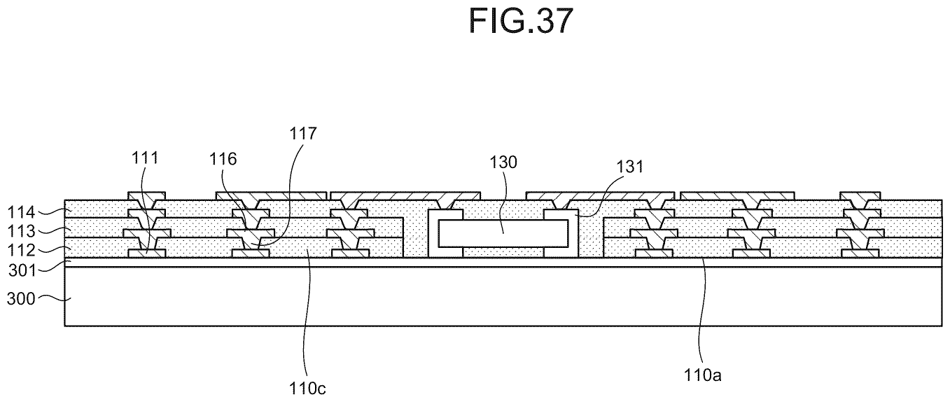

In a case where the resist layer 153 is removed, an unnecessary portion of the seed layer 114c is removed by flash etching (Step S152) so as to complete formation of the filling resin layer 114 of the first wiring structure 110. In other words, for example, as illustrated in FIG. 37, the seed layer 114c other than a part being in contact with the wiring layer 116 and the vias 117 is removed, and the filling resin layer 114 including an insulating layer, the wiring layer 116, and the vias 117 is laminated on the second thin film layer 113. FIG. 37 is a diagram illustrating a specific example of the seed layer removing process. Note that the seed layer 114c being in contact with the wiring layer 116 and the vias 117 remain after flash etching; however, illustration thereof is omitted in FIG. 37.

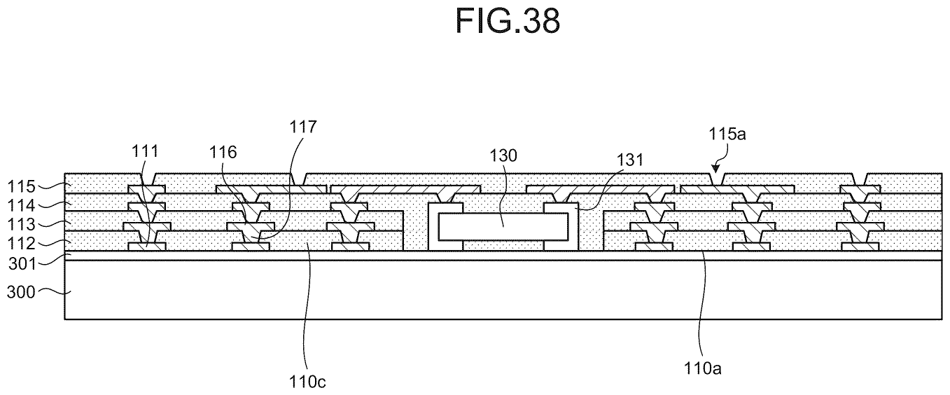

In a case where formation of the filling resin layer 114 of the first wiring structure 110 is completed, an insulating layer of the third thin film layer 115 is formed on the filling resin layer 114 so as to cover the wiring layer 116 (Step S153). The insulating layer is formed by using a photosensitive insulation resin material, and via holes are formed by photolithography. Specifically, for example, as illustrated in FIG. 38, in positions corresponding to the wiring layer 116 of the filling resin layer 114, via holes 115a are formed on the insulating layer of the third thin film layer 115, which expose upper surface of the wiring layer 116 of the filling resin layer 114. FIG. 38 is a diagram illustrating a specific example of the insulating layer forming process.

In positions where the via holes 115a are formed, the wiring layer 116 and the vias 117 of the third thin film layer 115 are formed (Step S154). Formation of the wiring layer 116 is performed by semi additive process, for example. The vias 117 are formed along with the wiring layer 116 so as to connect the wiring layer 116 of the third thin film layer 115 and the wiring layer 116 of the filling resin layer 114 to each other. Thus, formation of the first wiring structure 110, in which the electronic component 130 is embedded, is completed.

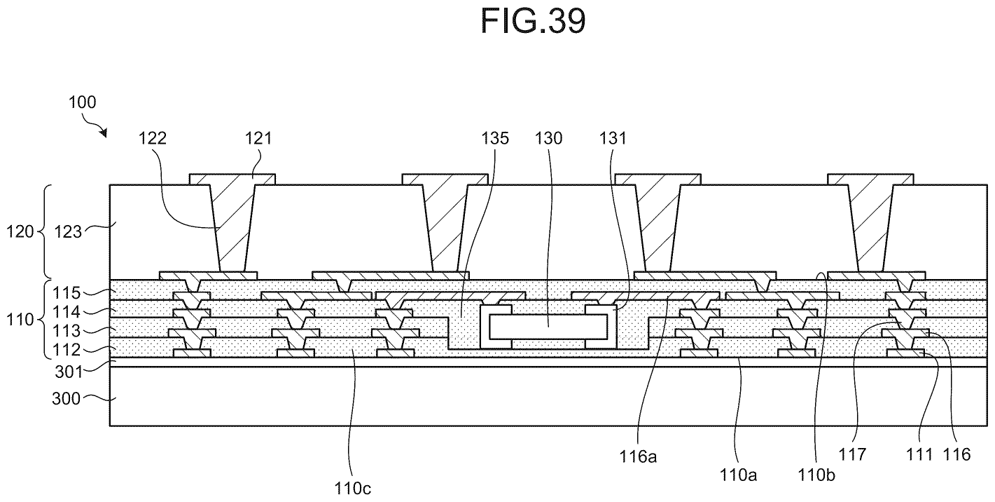

Next, various modifications according to the embodiment will be explained with reference to FIG. 39 to FIG. 48. Note that in the various modifications to be described below, the same reference symbol may be provided to a part that is the same as the above-mentioned embodiment so as to omit duplicated explanation.

FIG. 39 is a diagram illustrating a configuration of the first wiring board 100 according to a modification 1 of the embodiment. In the first wiring board 100 according to the modification 1, a fixing mode of the electronic component 130, which is embedded in the first thin film layer 112 and the second thin film layer 113, is different from that according to the above-mentioned embodiment.

Specifically, in the modification 1, a cavity of the first thin film layer 112 and the second thin film layer 113 does not penetrate up to the upper surface 110a of the first wiring structure 110, and a bottom surface of the cavity is formed by the insulating layer 110c of the first thin film layer 112. Moreover, the electronic component 130 is fixed onto the insulating layer 110c of the first thin film layer 112 forming a bottom surface of the cavity.

In the modification 1, the electronic component 130 is fixed onto the insulating layer 110c of the first thin film layer 112 forming a bottom surface of the cavity to be able to interpose the insulating layer 110c of the first thin film layer 112 between the electronic component 130 and the upper surface 110a of the first wiring structure 110. Thus, the electronic component 130 is not exposed from the upper surface 110a of the first wiring structure 110, so that it is possible to reduce a case where the electronic component 130 falls from the first wiring structure 110.

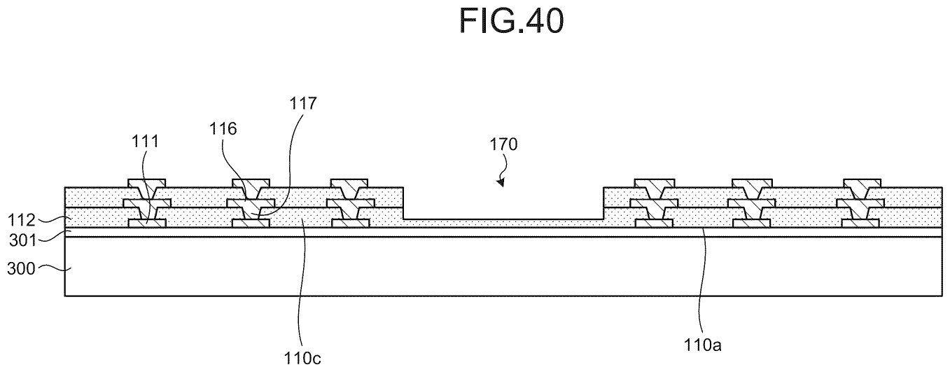

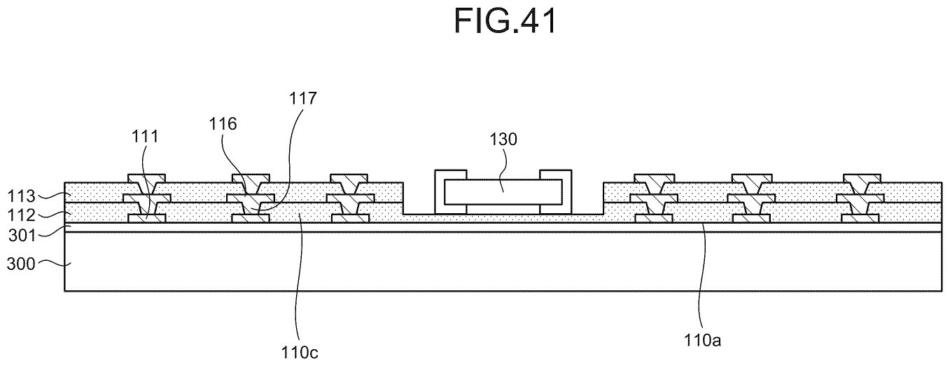

Subsequently, a manufacturing method for manufacturing the first wiring board 100 according to the modification 1 of the embodiment will be specifically explained with reference to FIG. 40 and FIG. 41. In the manufacturing method for manufacturing the first wiring board 100 according to the modification 1 differs from the embodiment in the cavity forming process (Step S144 illustrated in FIG. 16) and the electronic component arranging process (Step S145 illustrated in FIG. 16) of the forming process of the first wiring structure 110. FIG. 40 is a diagram illustrating a specific example of the cavity forming process. FIG. 41 is a diagram illustrating a specific example of the electronic component arranging process.

In a case where lamination of the first thin film layer 112 and the second thin film layer 113 is completed, a cavity is formed in a region in which the electronic component 130 is to be housed. Specifically, for example, as illustrated in FIG. 40, insulating layers of the first thin film layer 112 and the second thin film layer 113 are cut out up to a position that does not reach a surface (namely, upper surface 110a of first wiring structure 110) of the first thin film layer 112 located on an upper side of the glass support member 300 so as to form the cavity 170. A bottom surface of the cavity 170 is formed by the insulating layer 110c of the first thin film layer 112.

Next, the electronic component 130 is arranged in the cavity 170. Specifically, for example, as illustrated in FIG. 41, the electronic component 130 is temporarily bonded to the insulating layer 110c of the first thin film layer 112 located at a bottom surface the cavity 170 by an adhesive material (not illustrated) in a semi-cured state. In the later electronic component embedding process, thermosetting is performed on the adhesive agent that is temporarily bonding the electronic component 130 simultaneously with thermosetting of the filling resin layer 114 so that the electronic component 130 is fixed onto the insulating layer 110c of the first thin film layer 112 located at a bottom surface of the cavity 170. For example, an adhesive agent comprised of insulating resin, such as epoxy resin and polyimide resin, may be used as an adhesive agent for temporarily bonding the electronic component 130. The electronic component 130 is fixed onto the insulating layer 110c of the first thin film layer 112 located at a bottom surface of the cavity 170, and thus the insulating layer 110c of the first thin film layer 112 is interposed between the electronic component 130 and the upper surface 110a of the first wiring structure 110 so as to reduce a case of falling off of the electronic component 130.

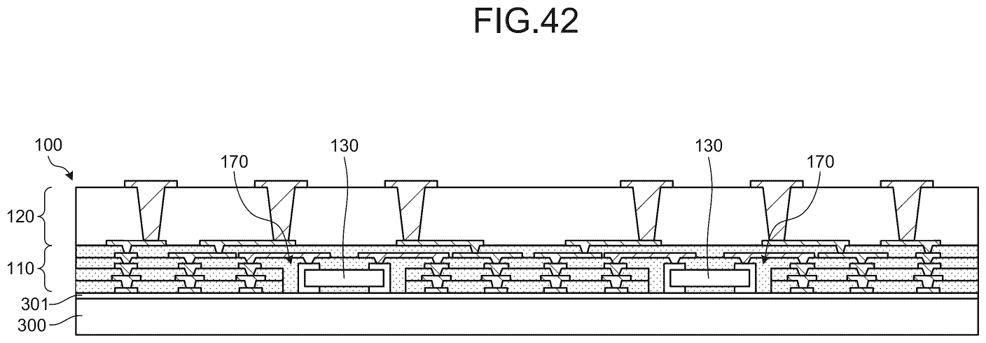

FIG. 42 is a diagram illustrating a configuration of the first wiring board 100 according to a modification 2 of the embodiment. The first wiring board 100 according to the modification 2 of the embodiment differs from the above-mentioned embodiment in that the plurality of electronic component 130 is embedded in the first wiring structure 110.

Specifically, in the modification 2, the plurality of cavities 170 is formed in insulating layers of the first thin film layer 112 and the second thin film layer 113 in the first wiring structure 110, and the plurality of electronic components 130 is respectively located in the plurality of cavities 170. The plurality of cavities 170 is filled with the filling resin layer 114 of the first wiring structure 110 so as to cover the plurality of electronic components 130. Thus, the plurality of electronic components 130 is embedded in the first wiring structure 110.

As described above, in the modification 2, the plurality of electronic components 130 is embedded in the first wiring structure 110, and thus noise from a semiconductor element can be effectively reduced by the plurality of electronic components 130, so that it is possible to more reduce diffusion of noise from the semiconductor element.

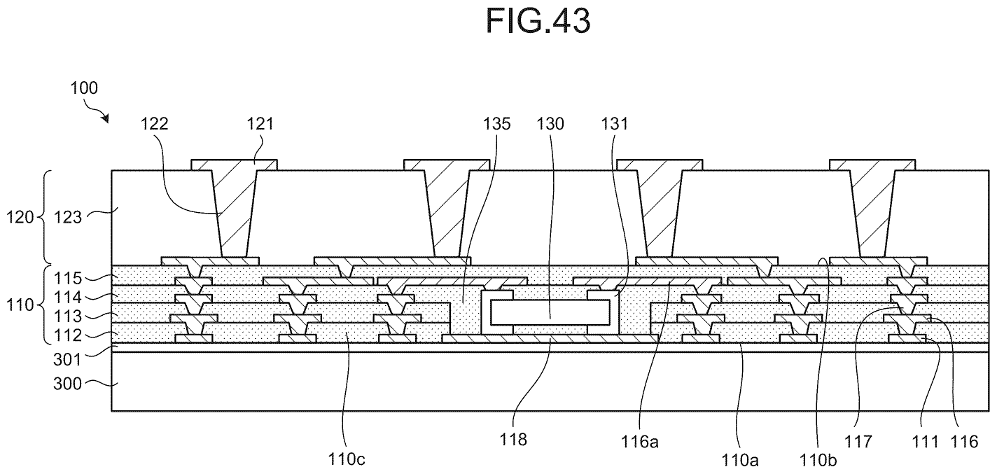

FIG. 43 is a diagram illustrating a configuration of the first wiring board 100 according to a modification 3 of the embodiment. The first wiring board 100 according to the modification 3 differs from the above-mentioned embodiment in a fixing mode of the electronic component 130 that is embedded in the first thin film layer 112 and the second thin film layer 113.

Specifically, in the modification 3, a pad 118, whose thickness is substantially equal to that of the electrode pad 111, is formed on the upper surface 110a of the first wiring structure 110, and further a cavity in the first thin film layer 112 and the second thin film layer 113 reaches up to the pad 118. Note that resist including an opening corresponding to a shape of the pad 118 may be used in forming the electrode pads 111 so as to form the pad 118. Next, the electronic component 130 is fixed onto the pad 118 that is exposed from a bottom surface of the cavity in the first thin film layer 112 and the second thin film layer 113.

In the modification 3, the electronic component 130 is fixed onto the pad 118 to be able to reduce a case where the electronic component 130 falls from the first wiring board 100.

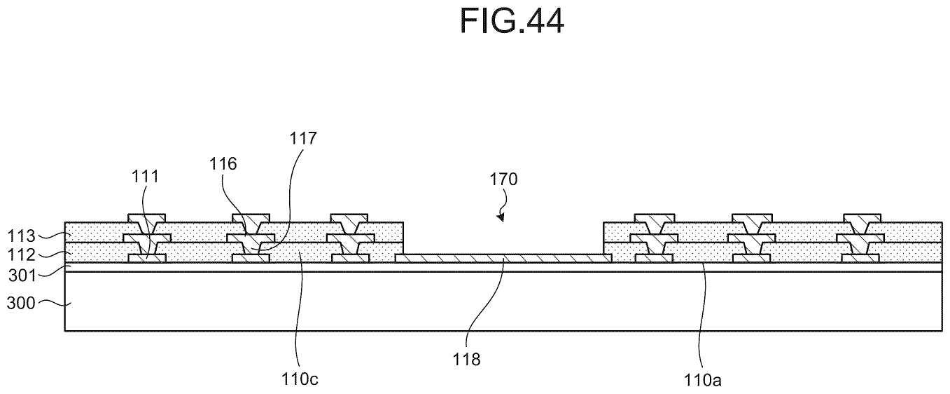

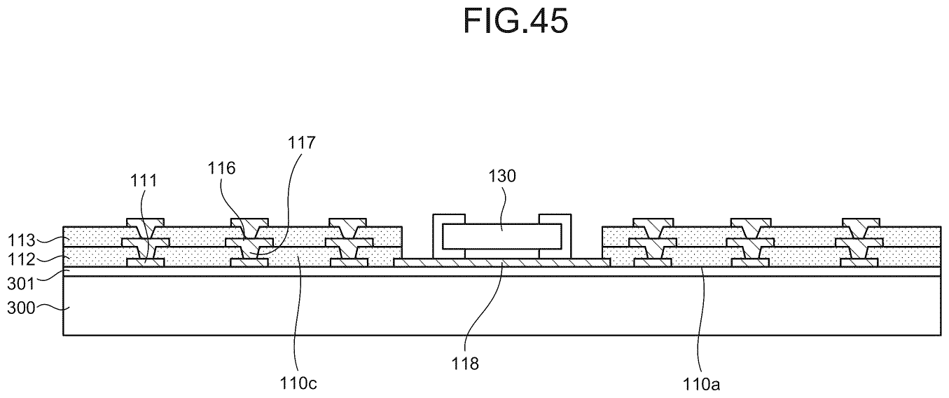

Subsequently, a manufacturing method for manufacturing the first wiring board 100 according to the modification 3 of the embodiment will be specifically explained with reference to FIG. 44 and FIG. 45. The manufacturing method for manufacturing the first wiring board 100 according to the modification 3 differs from the embodiment in the cavity forming process (Step S144 illustrated in FIG. 16) and the electronic component arranging process (Step S145 illustrated in FIG. 16) in the forming process of the first wiring structure 110. FIG. 44 is a diagram illustrating a specific example of the cavity forming process. FIG. 45 is a diagram illustrating a specific example of the electronic component arranging process. Note that in FIG. 44, assume that the pad 118 whose thickness is substantially equal to that of the electrode pad 111 is formed on the upper surface 110a of the first wiring structure 110 before performing the cavity forming process.

In a case where lamination of the first thin film layer 112 and the second thin film layer 113 is completed, a cavity is formed in a region in which the electronic component 130 is to be housed. Specifically, for example, as illustrated in FIG. 44, the insulating layers 110c of the first thin film layer 112 and the second thin film layer 113 are cut out up to the pad 118 so as to form the cavity 170. The cavity forming process can be realized by performing laser machining with the use of CO2 laser, for example. In the laser machining, the pad 118 functions as a stopping layer with respect to laser light, and thus the cavity 170 is obtained whose bottom surface is flat. The pad 118 is exposed at a bottom surface of the cavity 170. The pad 118 has a plane shape (for example, rectangular shape) whose size is larger than that of a plane shape of the bottom surface of the cavity 170. Therefore, a side surface of the pad 118 is located outer than a side surface of the cavity 170.

Next, the electronic component 130 is arranged in the cavity 170. Specifically, for example, as illustrated in FIG. 45, the electronic component 130 is temporarily bonded to the pad 118 located at a bottom surface the cavity 170 by an adhesive material (not illustrated) in a semi-cured state. In the later electronic component embedding process, thermosetting is performed on the adhesive agent that is temporarily bonding the electronic component 130 simultaneously with thermosetting of the filling resin layer 114 so that the electronic component 130 is fixed onto the pad 118 located at a bottom surface of the cavity 170. The electronic component 130 is fixed onto the pad 118 located at a bottom surface of the cavity 170 so as to reduce a case where the electronic component 130 falls from the first wiring board 100. Next, the processes of Step S146 and the following illustrated in FIG. 16 are performed so as to complete the first wiring board 100 according to the modification 3.

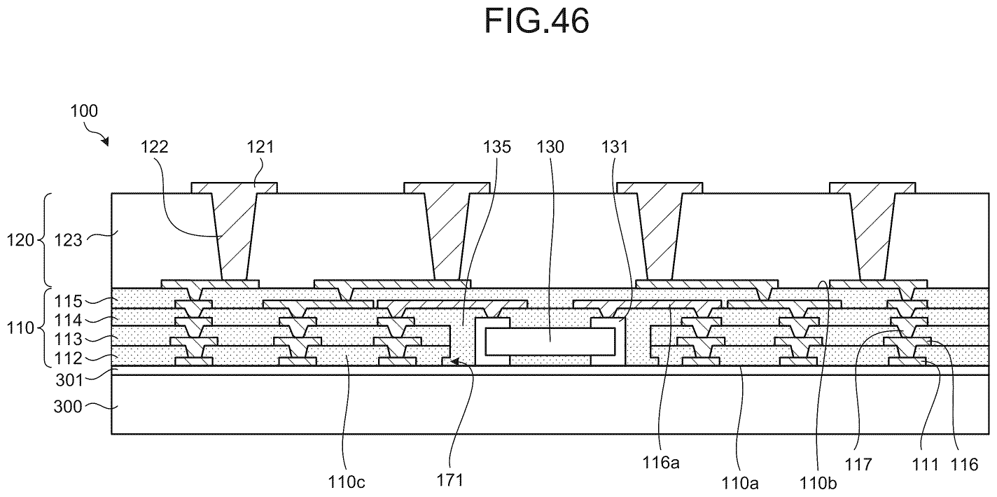

FIG. 46 is a diagram illustrating a configuration of the first wiring board 100 according to a modification 4 of the embodiment. The first wiring board 100 according to the modification 4 differs from the above-mentioned embodiment in a structure of a cavity in the first thin film layer 112 and the second thin film layer 113, and a structure of the filling resin layer 114.

Specifically, in the modification 4, side surfaces of a cavity in the first thin film layer 112 and the second thin film layer 113 include concave parts 171 at positions adjacent to a bottom surface of the cavity. Next, a part of the filling resin layer 114 (namely, filling resin 135) is stored in the concave parts 171 of the cavity.

In the modification 4, a part of the filling resin layer 114 is stored in the concave parts 171 of the cavity, so that it is possible to improve, by anchor effects, adhesiveness between the filling resin layer 114 and a cavity in the first thin film layer 112 and the second thin film layer 113.

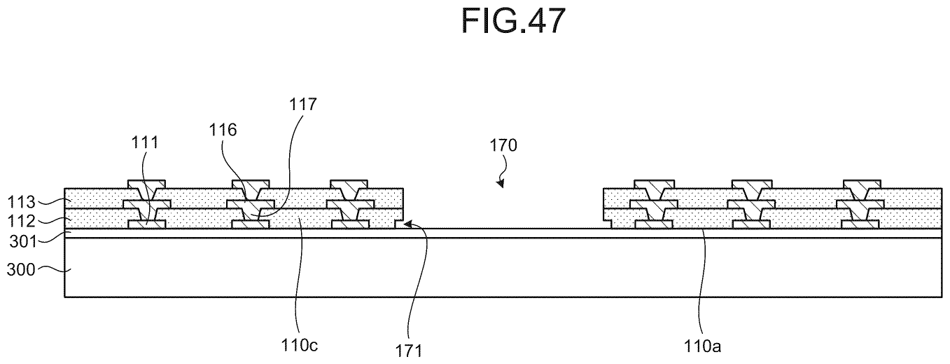

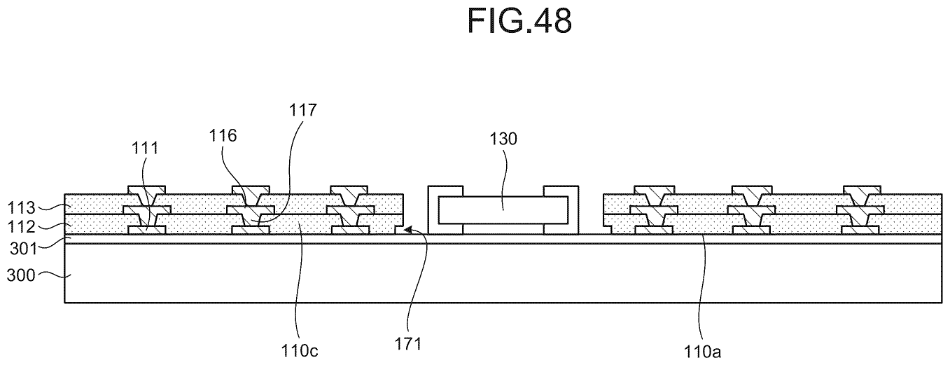

Subsequently, a manufacturing method for manufacturing the first wiring board 100 according to the modification 4 of the embodiment will be specifically explained with reference to FIG. 47 and FIG. 48. The manufacturing method for manufacturing the first wiring board 100 according to the modification 4 differs from the modification 3 in that a concave part forming process is included between the cavity forming process and the electronic component arranging process. Moreover, an electronic component arranging process of the manufacturing method for manufacturing the first wiring board 100 according to the modification 4 differs from that according to the modification 3. FIG. 47 is a diagram illustrating a specific example of a concave part forming process. FIG. 48 is a diagram illustrating a specific example of the electronic component arranging process.

In a case where the cavity 170, which reaches up to the pad 118, is formed in the first thin film layer 112 and the second thin film layer 113 (see FIG. 44), the concave parts 171 are formed on side surfaces of the cavity 170. Specifically, the pad 118 is removed by etching, for example, as illustrated in FIG. 47, the concave parts 171 are formed on side surfaces of the cavity 170. The peeling layer 301 is exposed at a bottom surface of the cavity 170.

Next, the electronic component 130 is arranged in the cavity 170. Specifically, for example, as illustrated in FIG. 48, the electronic component 130 is temporarily bonded to the peeling layer 301 in the cavity 170. In the later electronic component embedding process, the electronic component 130 is fixed onto the peeling layer 301 in the cavity 170 by thermosetting of the filling resin layer 114. Furthermore, in the electronic component embedding process, a part of the filling resin layer 114 (namely, filling resin 135) is stored in the concave parts 171 of the cavity 170, so that it is possible to improve, by anchor effects, adhesiveness between the filling resin layer 114 and the cavity 170. Next, the processes of Step S146 and the following illustrated in FIG. 16 are performed so as to complete the first wiring board 100 of the modification 4.

As described above, a wiring board (for one example, first wiring board 100) according to the embodiment includes a first wiring structure (for one example, first wiring structure 110) and a second wiring structure (for one example, second wiring structure 120). The first wiring structure includes: a mounting surface (for one example, upper surface 110a) of a semiconductor element; and a back surface (for one example, lower surface 110b) on an opposite side of the mounting surface. The second wiring structure is formed on the back surface of the first wiring structure. The first wiring structure includes thin film layers (for one example, first thin film layer 112 and second thin film layer 113), an electronic component (for one example, electronic component 130), and a filling resin layer (for one example, filling resin layer 114). The thin film layers include laminated wiring layers (for one example, wiring layers 116) and laminated insulating layers (for one example, insulating layers 110c). The electronic component is located in the cavity (for one example, cavity 170) that is formed by cutting out at least one of the insulating layers of the thin film layers in a direction toward the mounting surface. The filling resin layer that fills the cavity, and further covers the electronic component. Thus, it is possible to reduce diffusion of noise from the semiconductor element.

According to an aspect of a wiring board disclosed herein, it is possible to reduce diffusion of noise from a semiconductor element.

(Note 1) A manufacturing method of a wiring board, comprising:
forming a first wiring structure that includes a mounting surface for a semiconductor element and a back surface on an opposite side of the mounting surface; and
forming a second wiring structure on the back surface of the first wiring structure, wherein
the forming the first wiring structure includes:
   forming thin film layers that include laminated wiring layers and laminated insulating layers;
   forming a cavity by cutting out at least one of the insulating layers of the thin film layers in a direction toward the mounting surface;
   arranging an electronic component in the formed cavity; and
   filling the cavity with a filling resin that covers the electronic component.

(Note 2) The manufacturing method of the wiring board according to the Note 1, wherein
the forming the first wiring structure further includes:
   preparing a support member; and
   forming the first wiring structure on the support member such that the mounting surface is in contact with the support member.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board comprising:
a first wiring structure that includes a mounting surface for a semiconductor element and a back surface on an opposite side of the mounting surface; and
a second wiring structure that is formed on the back surface of the first wiring structure, wherein
the first wiring structure includes:
thin film layers that include laminated wiring layers and laminated insulating layers;
a cavity that is formed by cutting out at least one of the insulating layers of the thin film layers in a direction toward the mounting surface;
an electronic component that is located in the cavity; and
a filling resin layer that fills the cavity, and further covers the electronic component.

2. The wiring board according to claim 1, wherein
the electronic component is located in the cavity that is formed by cutting out the at least one of the insulating layers of the thin film layers up to the mounting surface, and is exposed at the mounting surface.

3. The wiring board according to claim 1, wherein
the electronic component is located in the cavity that is formed by cutting out the at least one of the insulating layers of the thin film layers up to a position that does not reach the mounting surface, and is fixed onto one of the insulating layers of one of the thin film layers forming a bottom surface of the cavity.

4. The wiring board according to claim 1, wherein
the first wiring structure includes a plurality of electronic components including the electronic component;
the plurality of electronic components are respectively located in a plurality of cavities including the cavity, each of the plurality of cavities being formed by cutting out the at least one of the insulating layers of the thin film layers in a direction toward the mounting surface; and
the filling resin layer fills the plurality of cavities, and further covers the plurality of electronic components.

5. The wiring board according to claim 1, wherein
a thickness of the first wiring structure is equal to or less than a thickness of the second wiring structure.

6. The wiring board according to claim 1 further comprising:
a support member, wherein
the first wiring structure is formed on an upper surface of the support member in a state where the mounting surface faces an upper surface side of the support member.

7. A laminated wiring board in which a wiring board is laminated on another wiring board, wherein
the wiring board includes:
a first wiring structure that includes a mounting surface for a semiconductor element and a back surface on an opposite side of the mounting surface; and
a second wiring structure that is laminated on the back surface of the first wiring structure, wherein
the first wiring structure includes:
thin film layers that include laminated wiring layers and laminated insulating layers;
a cavity that is formed by cutting out at least one of the insulating layers of the thin film layers in a direction toward the mounting surface;
an electronic component that is located in the cavity; and
a filling resin layer that fills the cavity, and further covers the electronic component.

8. The laminated wiring board according to claim 7, wherein
an electrode pad is provided on an opposite surface of the second wiring structure, the opposite surface being on an opposite side of the first wiring structure,
another electrode pad is provided on a surface of the other wiring board, and
the electrode pad and the other electrode pad are electrically connected to each other, and the wiring board is laminated on the other wiring board.
